(19) United States
(12) Patent Application Publication
(10) Pub. No.: US 2026/0190437 A1
(43) Pub. Date: Jul. 2, 2026

(54) SEMICONDUCTOR DEVICE AND METHODS OF FORMING THE SAME

(71) Applicant: Taiwan Semiconductor Manufacturing Co., Ltd., Hsinchu (TW)

(72) Inventors: Yan-Ting Lin, Baoshan Township (TW); Chien-I Kuo, Zhubei City (TW); Ming-Hua Yu, Hsinchu (TW); Chii-Horng Li, Zhubei City (TW)

(21) Appl. No.: 19/007,735

(22) Filed: Jan. 2, 2025

(51) Int. Cl. H10D 84/01; H10D 30/00; H10D 30/01; H10D 30/43; H10D 62/00; H10D 62/10; H10D 62/13; H10D 62/40; H10D 64/01; H10D 84/83

(52) U.S. Cl. CPC H10D 84/013; H10D 30/014; H10D 30/0191; H10D 30/43; H10D 30/501; H10D 62/021; H10D 62/121; H10D 62/151; H10D 62/405; H10D 64/017; H10D 84/0128; H10D 84/0133; H10D 84/8311; H10D 84/83125; H10D 84/832

(57) ABSTRACT

A method includes forming a stack of semiconductor layers over a substrate; etching the stack to form a first fin and a second fin, the first fin having a first width, the second fin having a second width, the second width being greater than the first width; etching a first recess in the first fin and a second recess in the second fin; performing a deposition process to grow a first epitaxial region in the first recess and a second epitaxial region in the second recess; wherein at a first point in the deposition process, a first raised height of the first epitaxial region is higher than a second raised height of the second epitaxial region; and wherein at a second point in the deposition process, a third raised height of the first epitaxial region is lower than a fourth raised height of the second epitaxial region.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional challenges arise that may be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a three-dimensional view of an exemplary nanostructure field-effect transistor (nano-FET), in accordance with some embodiments.

FIGS. 2-18E, illustrate varying views of intermediary steps of manufacturing a nano-FET transistor, in accordance with some embodiments.

FIGS. 19A-24B illustrate varying views of intermediary steps of forming source/drain regions of a nano-FET transistor, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In various embodiments, transistors are formed over a semiconductor substrate. The transistors may be nano-FETs (e.g., p-type nano-FETs), although any suitable types of transistors may utilize the embodiments disclosed herein. In accordance with some embodiments, a first fin and a second fin are formed over the semiconductor substrate, first dummy gate structures are formed across the first fin and second dummy gate structures are formed across the second fin. The first fin has a narrow width and the second fin has a wide width. A first recess may be etched into the first fin between the first dummy gate structures, and a second recess may be etched into the second fin between the second dummy gate structures. Epitaxial source/drain regions are formed, such that a first epitaxial region is formed in the first recess and a second epitaxial region is formed in the second recess. Embodiments of forming the epitaxial source/drain regions prevent or reduce certain loading effects associated with the differences between the first width and the second width. For example, during an initial stage, the growth rate of the first epitaxial region is faster than the growth rate of the second epitaxial region. During a later stage, the growth rate of the second epitaxial region is greater than the growth rate of the first epitaxial region. The dynamic relationships between the growth rates provide greater control, such as ensuring that the second epitaxial region has a raised height that is greater than or equal to a raised height of the first epitaxial region. As a result, subsequent formation of contact plugs to each of the epitaxial source/drain regions may be performed simultaneously, while providing adequate contact area in both cases for improved yield and performance of the transistors and overall integrated circuit device.

Embodiments are described below in a particular context, a die comprising nano-FETs. Various embodiments may be applied, however, to dies comprising other types of transistors (e.g., stacking transistors, or the like) in lieu of or in combination with the nano-FETs.

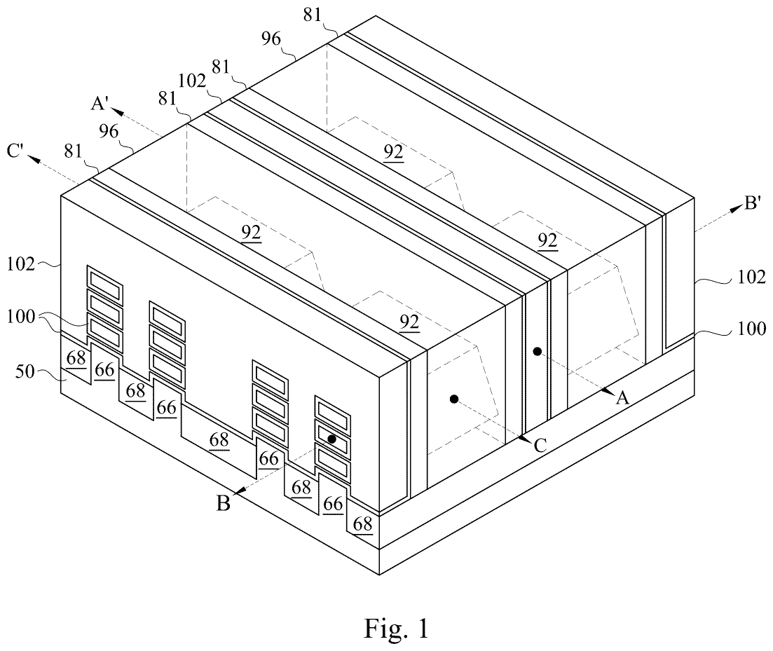

FIG. 1 illustrates an example of nano-FETs (e.g., nanowire FETs, nanosheet FETs (Nano-FETs), or the like) in a three-dimensional view, in accordance with some embodiments. Certain features are simplified and/or omitted in FIG. 1 for ease of illustration. The nano-FETs comprise nanostructures 54 (e.g., nanosheets, nanowires, or the like) over fins 66 on a substrate 50 (e.g., a semiconductor substrate), wherein the nanostructures 54 act as channel regions for the nano-FETs. The nanostructure 54 may include p-type nanostructures, n-type nanostructures, or a combination thereof. Shallow trench isolation (STI) regions 68 (also referred to as STI structures or STI regions) are disposed between adjacent fins 66, which may protrude above and from between neighboring STI regions 68. Although the STI regions 68 are described/illustrated as being separate from the substrate 50, as used herein, the term “substrate” may refer to the semiconductor substrate alone or a combination of the semiconductor substrate and the isolation regions. Additionally, although a bottom portion of the fins 66 are illustrated as being single, continuous materials with the substrate 50, the bottom portion of the fins 66 and/or the substrate 50 may comprise a single material or a plurality of materials. In this context, the fins 66 refer to the portions extending between the neighboring STI regions 68.

In some embodiments, the semiconductor substrate 50 may have a (001) or (110) crystal orientation. As discussed in greater detail below, the (110) orientation facilitates some advantageous growth patterns of epitaxial layers that will be formed in subsequent steps (e.g., formation of source/drain regions). This may provide greater control and additional options for the formation of such epitaxial layers along semiconductor surfaces of varying shapes and sizes. In accordance with various embodiments, a source/drain region formed over a (110) oriented substrate may have upper facets along the Z-plane to Y-plane with angles of 35.3°, while analogous upper facets of a source/drain region formed over a (001) oriented substrate may have angles of 54.7°. As such, sheet coverage may improve with the (110) orientation. In addition, the final critical dimensions of the source/drain regions along the Y-direction may be larger on the (110) oriented substrate as compared to the (001) oriented substrate. As a result, the source/drain regions on the (110) oriented substrate may have a lower raise height (e.g., growing at a slower rate) in the Z-direction than on the (001) oriented substrate. Further, the raise height difference between source/drain regions of different sizes (e.g., different channel widths) will also be reduced with the (110) orientation.

Gate dielectric layers 100 are over top surfaces of the fins 66 and along top surfaces, sidewalls, and bottom surfaces of the nanostructures 54. Gate electrodes 102 are over the gate dielectric layers 100. Epitaxial source/drain regions 92 are disposed on the fins 66 on opposing sides of the gate dielectric layers 100 and the gate electrodes 102. Source/drain region(s) 92 may refer to a source or a drain, individually or collectively dependent upon the context.

FIG. 1 further illustrates reference cross-sections that are used in later figures. Cross-section A-A′ is along a longitudinal axis of a gate electrode 102 and in a direction, for example, perpendicular to the direction of current flow between the epitaxial source/drain regions 92 of a nano-FET. Cross-section B-B′ is perpendicular to cross-section A-A′ and is parallel to a longitudinal axis of a fin 66 of the nano-FET and in a direction of, for example, a current flow between the epitaxial source/drain regions 92 of the nano-FET. Cross-section C-C′ is parallel to cross-section A-A′ and extends through epitaxial source/drain regions of the nano-FETs. Subsequent figures refer to these reference cross-sections for clarity.

Some embodiments discussed herein are discussed in the context of nano-FETs formed using a gate-last process. In other embodiments, a gate-first process may be used. Also, some embodiments contemplate aspects used in planar devices, such as planar FETs or in fin field-effect transistors (FinFETs).

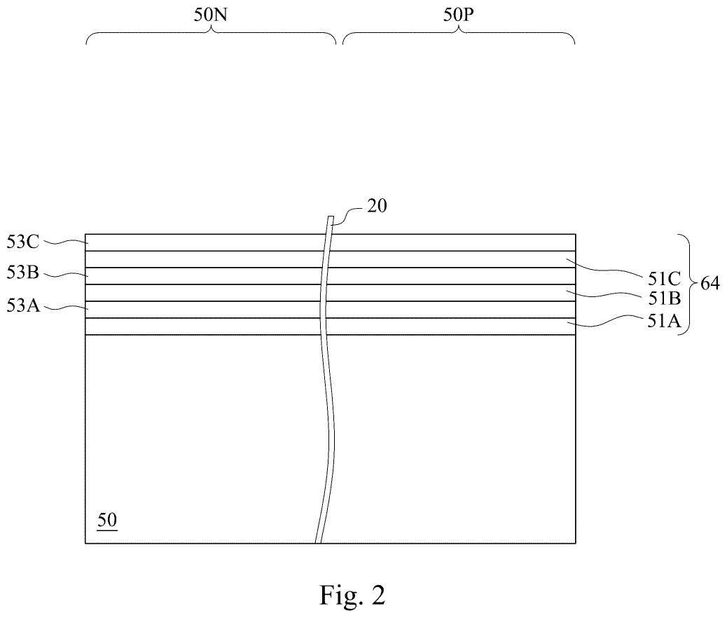

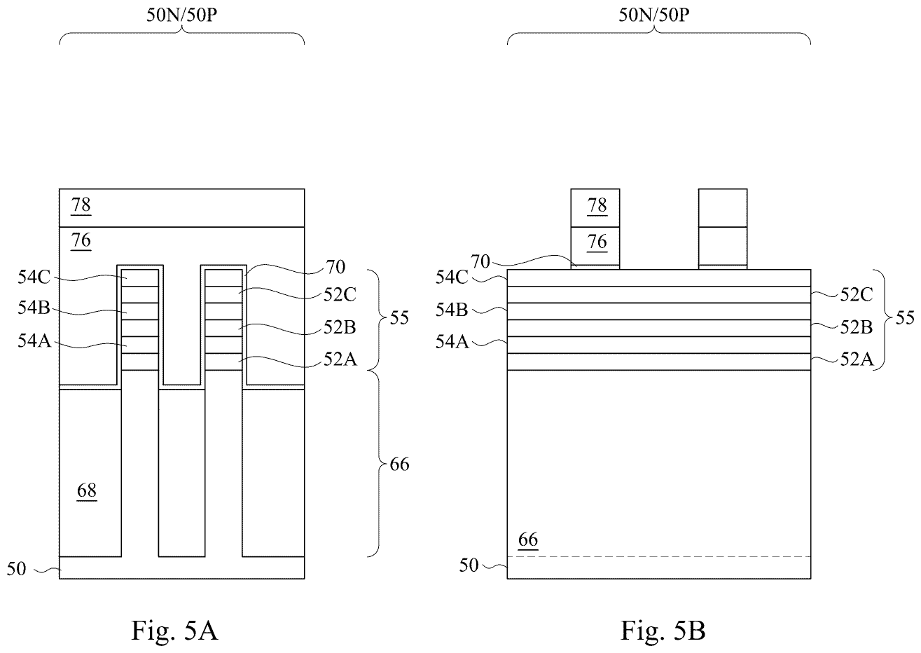

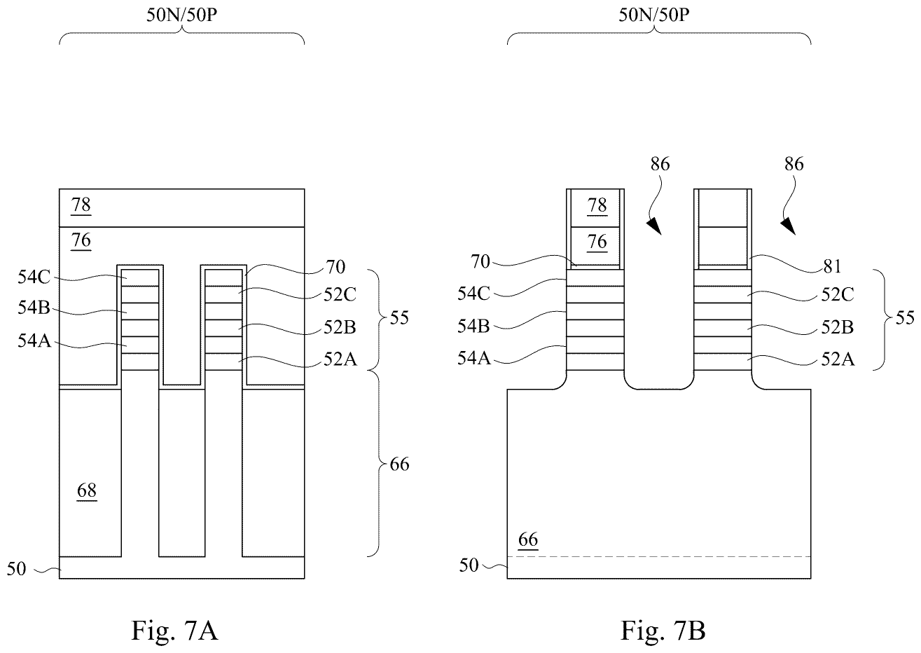

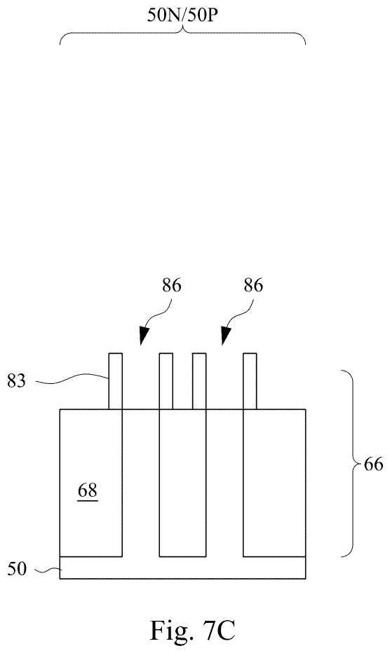

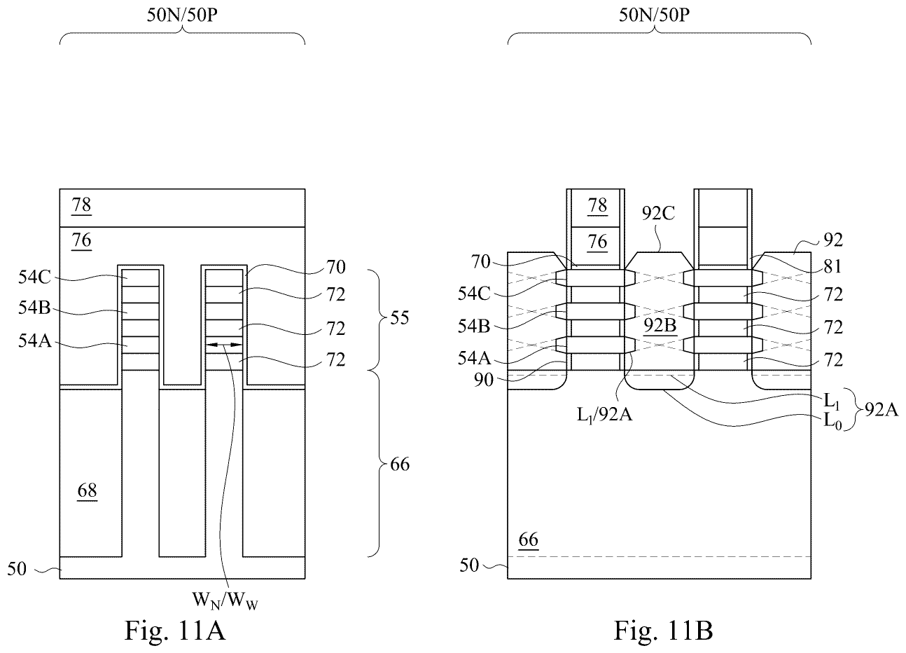

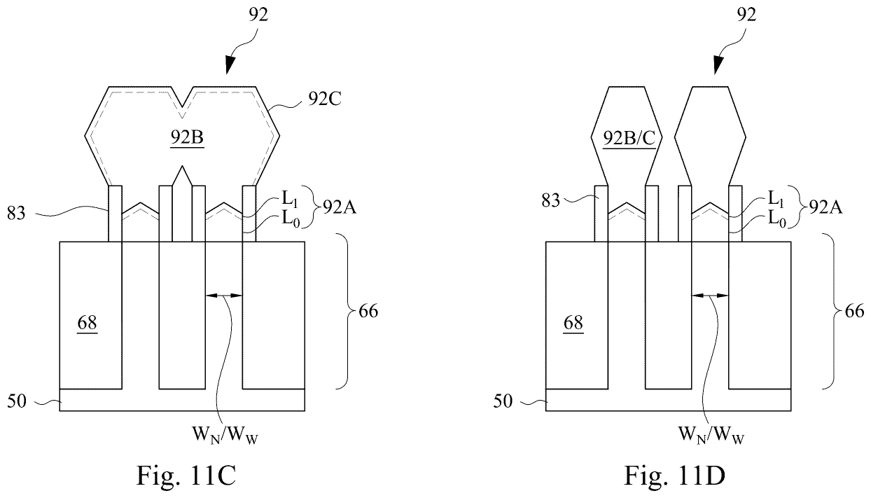

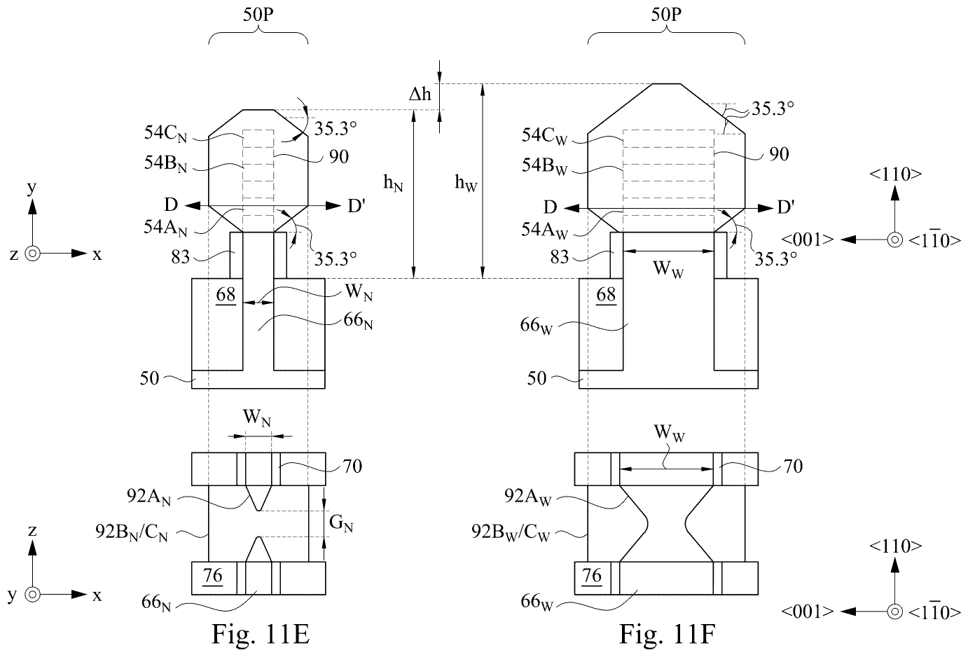

FIGS. 2 through 24B are cross-sectional views of intermediate stages in the manufacturing of nano-FETs, in accordance with some embodiments. FIGS. 2, 3, 4, 5A, 6A, 7A, 8A, 9A, 10A, 11A, 12A, 13A, 14A, 15A, 16A, 17A, and 18A illustrate reference cross-section A-A′ illustrated in FIG. 1. FIGS. 5B, 6B, 7B, 8B, 9B, 10B, 10C, 10D, 11B, 12B, 13B, 14B, 15B, 15C, 16B, 17B, and 18B illustrate reference cross-section B-B′ illustrated in FIG. 1. FIGS. 7C, 11C, 11D, 11E, 11F, 16C, 17C, 18C, 18D, 18E, 22A, 22B, 23A, 23B, 24A, and 24B illustrate reference cross-section C-C′ illustrated in FIG. 1. FIGS. 11E, 11F, 18D, 18E, 19A, 19B, 20A, 20B, 21A, 21B, 22A, 22B, 23A, 23B, 24A, and 24B illustrate plan view cross-section D-D′ illustrated in various corresponding figures.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 50 has an n-type region 50N and a p-type region 50P. The n-type region 50N can be for forming n-type devices, such as NMOS transistors, e.g., n-type nano-FETs, and the p-type region 50P can be for forming p-type devices, such as PMOS transistors, e.g., p-type nano-FETs. The n-type region 50N may be physically separated from the p-type region 50P (as illustrated by divider 20), and any number of device features (e.g., other active devices, doped regions, isolation structures, etc.) may be disposed between the n-type region 50N and the p-type region 50P. Although one n-type region 50N and one p-type region 50P are illustrated, any number of n-type regions 50N and p-type regions 50P may be provided. Subsequent figures describe processing steps that may be performed in either the n-type region 50N or the p-type region 50P unless otherwise noted.

Further in FIG. 2, a multi-layer stack 64 is formed over the substrate 50. The multi-layer stack 64 includes alternating layers of first semiconductor layers 51A-C (collectively referred to as first semiconductor layers 51) and second semiconductor layers 53A-C (collectively referred to as second semiconductor layers 53). For purposes of illustration and as discussed in greater detail below, the first semiconductor layers 51 will be removed and the second semiconductor layers 53 will be patterned to form channel regions of nano-FETs in both the n-type region 50N and the p-type region 50P. Nevertheless, in some embodiments, the second semiconductor layers 53 may be removed and the first semiconductor layers 51 may be patterned to form channel regions of nano-FETs in both the n-type region 50N and the p-type region 50P. For example, the channel regions in both the n-type region 50N and the p-type region 50P may have a same material composition (e.g., silicon, or another semiconductor material) and be formed simultaneously.

In other embodiments, the first semiconductor layers 51 may be removed and the second semiconductor layers 53 may be patterned to form channel regions of nano-FETs in the p-type region 50P, and the second semiconductor layers 53 may be removed and the first semiconductor layers 51 may be patterned to form channel regions of nano-FETs in the n-type region 50N. In still other embodiments, the first semiconductor layers 51 may be removed and the second semiconductor layers 53 may be patterned to form channel regions of nano-FETs in the n-type region 50N, and the second semiconductor layers 53 may be removed and the first semiconductor layers 51 may be patterned to form channel regions of nano-FETs in the p-type region 50P. In such embodiments, the channel regions of the n-type region 50N may have a different material composition than the channel regions of the p-type region 50P. The first semiconductor layers 51 and the second semiconductor layers 53 may be selectively removed from each of the n-type region 50N and p-type region 50P through additional masking and etching steps. For example, the channel regions of the n-type region 50N may be silicon channel regions while the channel regions of the p-type region 50P may be silicon germanium channel regions.

The multi-layer stack 64 is illustrated as including three layers of each of the first semiconductor layers 51 and the second semiconductor layers 53 for illustrative purposes. In some embodiments, the multi-layer stack 64 may include any number of the first semiconductor layers 51 and the second semiconductor layers 53. Each of the layers of the multi-layer stack 64 may be epitaxially grown using a process such as chemical vapor deposition (CVD), atomic layer deposition (ALD), vapor phase epitaxy (VPE), molecular beam epitaxy (MBE), or the like.

In various embodiments, the first semiconductor layers 51 may be formed of a first semiconductor material, such as silicon germanium, or the like, and the second semiconductor layers 53 may be formed of a second semiconductor material, such as silicon, silicon carbon, or the like. The first semiconductor materials and the second semiconductor materials may be materials having a high-etch selectivity to one another. As such, the first semiconductor layers 51 of the first semiconductor material may be removed without significantly removing the second semiconductor layers 53 of the second semiconductor material, thereby allowing the second semiconductor layers 53 to be patterned to form channel regions of the nano-FETs.

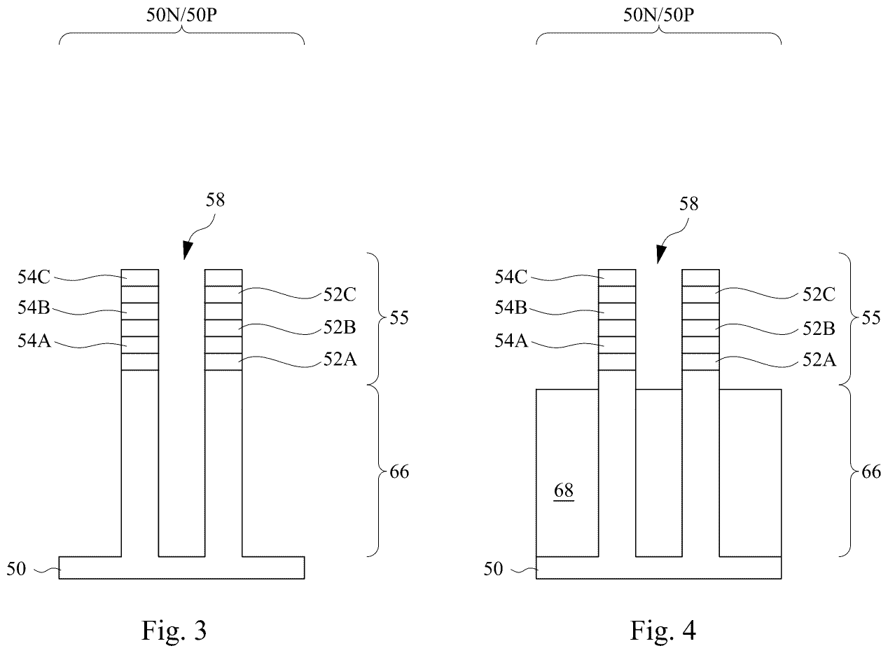

Referring now to FIG. 3, fins 66 are formed in the substrate 50 and nanostructures 55 are formed in the multi-layer stack 64 (shown in FIG. 2), in accordance with some embodiments. In some embodiments, the nanostructures 55 and the fins 66 may be formed in the multi-layer stack 64 (shown in FIG. 2) and the substrate 50, respectively, by etching trenches 58 in the multi-layer stack 64 (shown in FIG. 2) and the substrate 50. The etching may be any acceptable etch process, such as a reactive ion etch (RIE), neutral beam etch (NBE), the like, or a combination thereof. The etching may be anisotropic. During the etching process, a hard mask may be used to define a pattern of the fins 66 and the nanostructures 55. The hard mask may comprise any suitable insulating material, such as an oxide, a nitride, and oxynitride, and oxycarbonitride, or the like. In some embodiments (not separately illustrated), the hard mask may be a multi-layer structure. The hard mask may be formed over the nanostructures 55 using an acceptable process(es) such as thermal oxidation, physical vapor deposition (PVD), CVD, ALD, combinations thereof, or the like.

The fins 66 and the nanostructures 55 may be patterned by any suitable method. For example, the fins 66 and the nanostructures 55 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, a sacrificial layer is formed over a substrate and patterned using a photolithography process. Spacers are then formed alongside the patterned sacrificial layer using a self-aligned process. The sacrificial layer is then removed, and the remaining spacers may then be used to pattern the fins 66 and the nanostructures 55.

Forming the nanostructures 55 by etching the multi-layer stack 64 (shown in FIG. 2) may further define first nanostructures 52A-C (collectively referred to as the first nanostructures 52) from the first semiconductor layers 51 and define second nanostructures 54A-C (collectively referred to as the second nanostructures 54) from the second semiconductor layers 53. The first nanostructures 52 and the second nanostructures 54 may further be collectively referred to as the nanostructures 55.

FIG. 3 illustrates the fins 66 having substantially equal widths for illustrative purposes. In some embodiments, widths of the fins 66 in the n-type region 50N may be greater or thinner than the fins 66 in the p-type region 50P. Further, while FIG. 3 illustrates each of the fins 66 and the nanostructures 55 as having a consistent width throughout, in other embodiments, the fins 66 and/or the nanostructures 55 may have tapered sidewalls such that a width of each of the fins 66 and/or the nanostructures 55 continuously increases in a direction towards the substrate 50. In such embodiments, each of the nanostructures 55 may have a different width and be trapezoidal in shape.

In FIG. 4, shallow trench isolation (STI) regions 68 are formed adjacent the fins 66. The STI regions 68 may be formed by depositing an insulation material over the substrate 50, the fins 66, and nanostructures 55, and between adjacent fins 66 to fill the trenches 58. The insulation material may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In the illustrated embodiment, the insulation material is silicon oxide formed by an FCVD process. An anneal process may be performed once the insulation material is formed. In an embodiment, the insulation material is formed such that excess insulation material covers the nanostructures 55. Although the insulation material is illustrated as a single layer, some embodiments may utilize multiple layers. For example, in some embodiments a liner (not separately illustrated) may first be formed along a surface of the substrate 50, the fins 66, and the nanostructures 55. Thereafter, a fill material, such as those discussed above may be formed over the liner.

A removal process is then applied to the insulation material to remove excess insulation material over the nanostructures 55. In some embodiments, a planarization process such as a chemical mechanical polish (CMP), an etch-back process, combinations thereof, or the like may be utilized. The planarization process exposes the nanostructures 55 such that top surfaces of the nanostructures 55 and the insulation material are level after the planarization process is complete.

The insulation material is then recessed to form the STI regions 68. The insulation material is recessed such that upper portions of fins 66 protrude from between neighboring STI regions 68. Further, the top surfaces of the STI regions 68 may be flat surfaces as illustrated, convex surfaces, concave surfaces (such as dishing), or a combination thereof. The top surfaces of the STI regions 68 may be formed flat, convex, and/or concave by an appropriate etch. The STI regions 68 may be recessed using an acceptable etching process, such as one that is selective to the material of the insulation material (e.g., etches the material of the insulation material at a faster rate than the material of the fins 66 and the nanostructures 55). For example, an oxide removal using, for example, dilute hydrofluoric (dHF) acid may be used. Thereafter, an optional hard mask (not separately illustrated) may then be formed over the top surfaces of the STI regions 68 to cover the STI regions 68. The hard mask may be made of a nitride or other material that has etch selectivity to the STI regions 68 (e.g., etch selectivity to a fill material of the STI regions 68).

Further in FIG. 4, appropriate wells (not separately illustrated) may be formed in the first semiconductor layers 51, the second semiconductor layers 53, and/or the substrate 50. In embodiments with different well types, different implant steps for the n-type region 50N and the p-type region 50P may be achieved using a photoresist or other masks (not separately illustrated). For example, a photoresist may be formed over structures in the n-type region 50N and the p-type region 50P. The photoresist is patterned to expose the p-type region 50P. The photoresist can be formed by using a spin-on technique and can be patterned using acceptable photolithography techniques. Once the photoresist is patterned, an n-type impurity implant is performed in the p-type region 50P, and the photoresist may act as a mask to substantially prevent n-type impurities from being implanted into the n-type region 50N. The n-type impurities may be phosphorus, arsenic, antimony, or the like implanted in the region to a concentration in a range from about 10¹³ atoms/cm³ to about 10¹⁴ atoms/cm³. After the implant, the photoresist is removed, such as by an acceptable ashing process.

Following or prior to the implanting of the p-type region 50P, a photoresist or other masks (not separately illustrated) is formed over the structures in the p-type region 50P and the n-type region 50N. The photoresist is patterned to expose the n-type region 50N. The photoresist can be formed by using a spin-on technique and can be patterned using acceptable photolithography techniques. Once the photoresist is patterned, a p-type impurity implant may be performed in the n-type region 50N, and the photoresist may act as a mask to substantially prevent p-type impurities from being implanted into the p-type region 50P. The p-type impurities may be boron, boron fluoride, indium, or the like implanted in the region to a concentration in a range from about 10¹³ atoms/cm³ to about 10¹⁴ atoms/cm³. After the implant, the photoresist may be removed, such as by an acceptable ashing process.

After the implants of the n-type region 50N and the p-type region 50P, an anneal may be performed to repair implant damage and to activate the p-type and/or n-type impurities that were implanted. In some embodiments, the implantation process may be performed on the substrate 50 prior to forming the first semiconductor layers 51 and the second semiconductor layers 53. Subsequently, the grown materials of the first semiconductor layers 51 and/or the semiconductor layers 53 may be in situ doped during growth. Alternatively, the implantation process may be performed on one or more of the first semiconductor layers 51 and/or the second semiconductor layers 53.

In FIGS. 5A and 5B, dummy gates 76 are formed over and along sidewalls of the nanostructures 55 and the fin 66. To form the dummy gates 76, first, a dummy dielectric layer is formed on the fins 66 and/or the nanostructures 55. The dummy dielectric layer may be made of silicon oxide, silicon nitride, a combination thereof, or the like, and may be deposited or thermally grown according to acceptable techniques. A dummy gate layer is formed over the dummy dielectric layer, and a mask layer is formed over the dummy gate layer. The dummy gate layer may be deposited over the dummy dielectric layer and then planarized, such as by a CMP. The mask layer may be deposited over the dummy gate layer. The dummy gate layer may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer may be deposited by physical vapor deposition (PVD), CVD, sputter deposition, or other techniques for depositing the selected material. The dummy gate layer may be made of other materials that have a high etching selectivity from the etching of isolation regions. The mask layer may include, for example, silicon nitride, silicon oxynitride, or the like.

Subsequently, the mask layer may be patterned using acceptable photolithography and etching techniques to form masks 78. The pattern of the masks 78 then may be transferred to the dummy gate layer and to the dummy dielectric layer to form dummy gates 76 and dummy gate dielectrics 70, respectively. The dummy gates 76 cover respective channel regions of the fins 66. The pattern of the masks 78 may be used to physically separate each of the dummy gates 76 from adjacent dummy gates 76. The dummy gates 76 may also have a lengthwise direction substantially perpendicular to the lengthwise direction of respective fins 66. It is noted that the dummy gate dielectrics 70 is shown covering only the fins 66 and the nanostructures 55 for illustrative purposes only. In some embodiments, the dummy gate dielectrics 70 may be deposited such that the dummy gate dielectrics 70 covers the STI regions 68, such that the dummy gate dielectrics 70 extends between the dummy gates 76 and the STI regions 68.

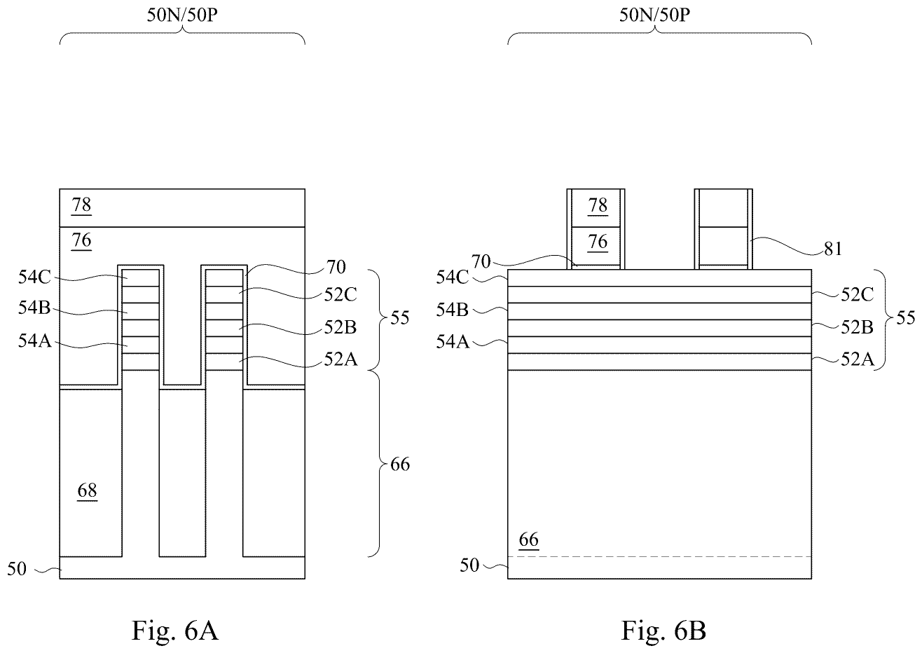

In FIGS. 6A and 6B, gate spacers 81 are formed over the nanostructures 55 and the STI regions 68, on exposed sidewalls of the masks 78 (if present), the dummy gates 76, and the dummy gate dielectrics 70. The gate spacers 81 may be formed by conformally forming one or more dielectric material(s) and subsequently etching the dielectric material(s). Acceptable dielectric materials may include silicon oxide, silicon nitride, silicon oxynitride, silicon oxycarbonitride, or the like, which may be formed by a deposition process such as chemical vapor deposition (CVD), atomic layer deposition (ALD), or the like. Other insulation materials formed by any acceptable process may be used. Any acceptable etch process, such as a dry etch, a wet etch, the like, or a combination thereof, may be performed to pattern the dielectric material(s). The etching may be anisotropic. The dielectric material(s), when etched, have portions left on the sidewalls of the dummy gates 76 (thus forming the gate spacers 81). As subsequently described in greater detail, the dielectric material(s), when etched, may also have portions left on the sidewalls of the semiconductor fins 66 and/or the nanostructures 55 (thus forming fin spacers 83, see FIG. 7C). After etching, the fin spacers 83 and/or the gate spacers 81 can have straight sidewalls (as illustrated) or can have curved sidewalls (not separately illustrated).

In FIGS. 7A-7C, first recesses 86 are formed in the fins 66, the nanostructures 55, and the substrate 50, in accordance with some embodiments. Epitaxial source/drain regions will be subsequently formed in the first recesses 86. The first recesses 86 may extend through the first nanostructures 52 and the second nanostructures 54, and into the substrate 50. As illustrated in FIG. 7C, top surfaces of the STI regions 68 may be level with bottom surfaces of the first recesses 86. In other embodiments, the fins 66 may be etched such that bottom surfaces of the first recesses 86 are disposed above or below the top surfaces of the STI regions 68. The first recesses 86 may be formed by etching the fins 66, the nanostructures 55, and the substrate 50 using anisotropic etching processes, such as RIE, NBE, or the like. The gate spacers 81, the fin spacers 83, and the masks 78 mask portions of the fins 66, the nanostructures 55, and the substrate 50 during the etching processes used to form the first recesses 86. A single etch process or multiple etch processes may be used to etch each layer of the nanostructures 55 and/or the fins 66. Timed etch processes may be used to stop the etching of the first recesses 86 after the first recesses 86 reach a desired depth.

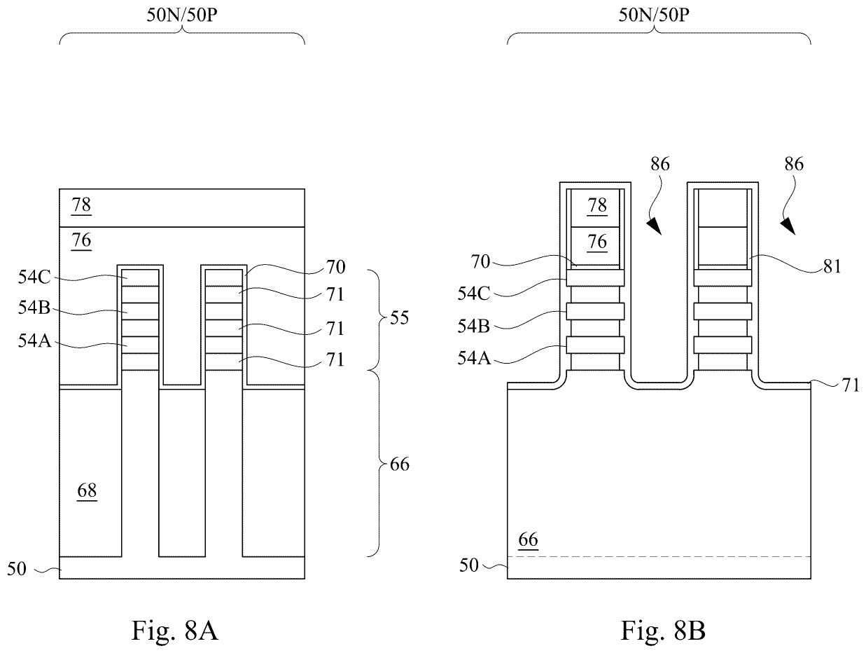

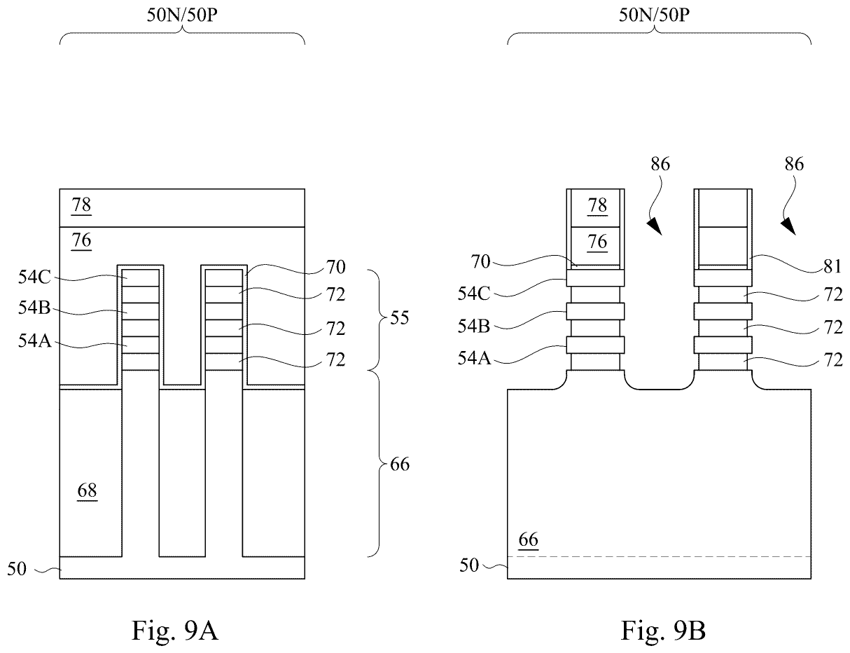

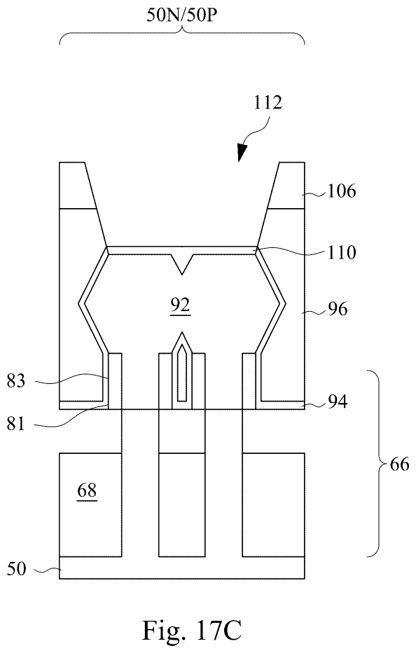

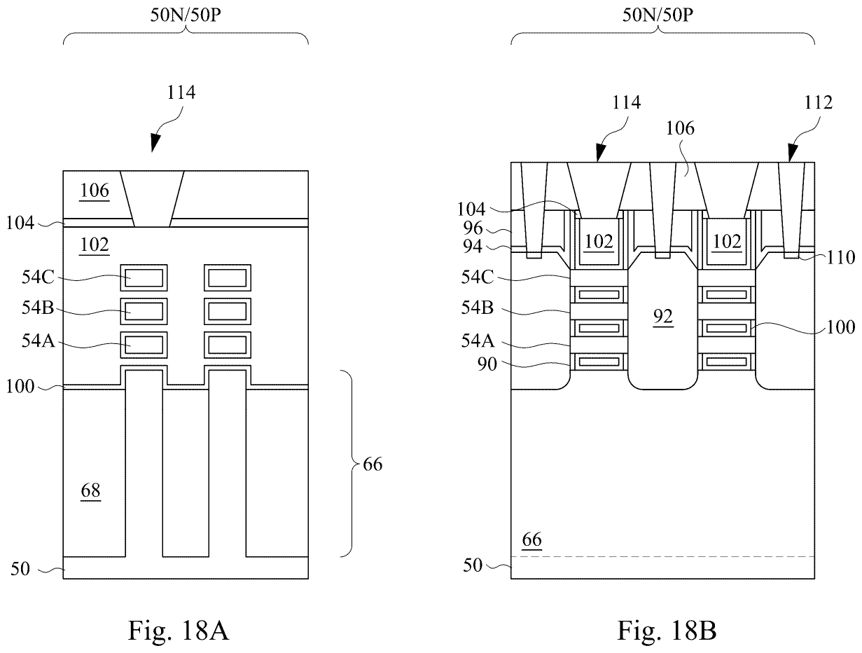

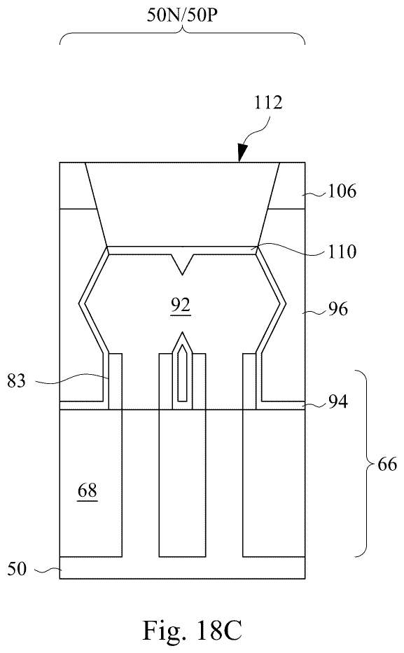

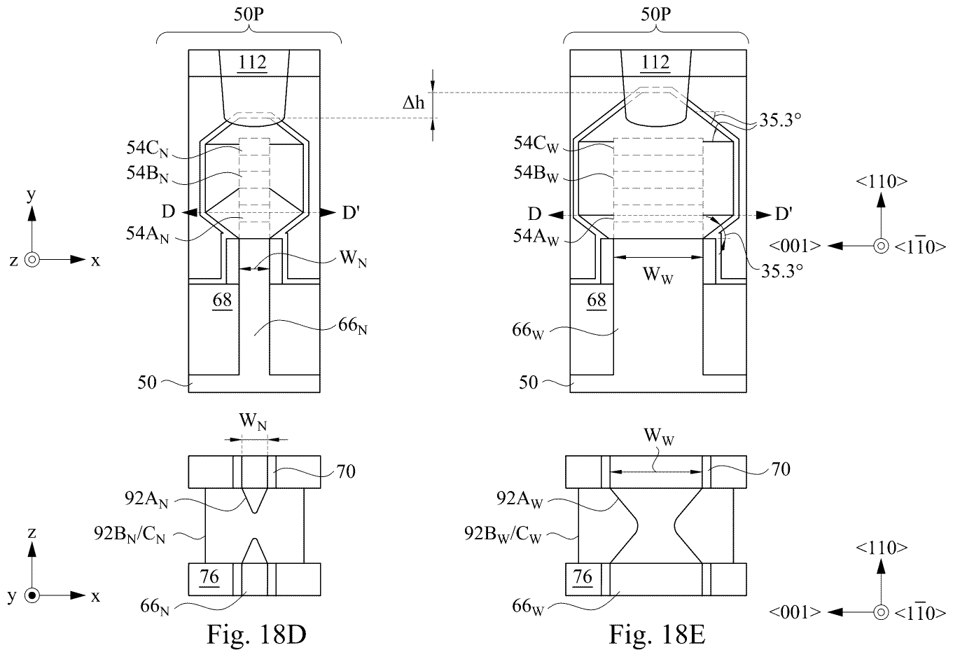

In FIGS. 8A-9B, the first nanostructures 52 are replaced with a sacrificial material 72 (also referred to as disposable oxide interposers (DOI) 72). Replacing the first nanostructures 52 may include etching away the first nanostructures 52 using a suitable etch process, such as an isotropic etch process, that is performed through the first recesses 86 as illustrated by FIGS. 8A-8B. The etch process may be selective to the material of the first nanostructures 52 and remove the first nanostructures 52 without significantly removing the second nanostructures 54 or the semiconductor fins 66. As such, the etch process may result in spaces or voids (not specifically illustrated) between adjacent second nanostructures 54. In some embodiments, the second nanostructures 54, particularly corner regions of the second nanostructures 54, may be slightly etched during the removal of the first nanostructures 52. For example, as a result of removing the first nanostructures 52, corners regions of the second nanostructures 54 are spaced farther apart that middle regions of the second nanostructures 54 (see e.g., FIG. 18C). In an embodiment in which the first nanostructures 52 include, e.g., SiGe, and the second nanostructures 54 include, e.g., Si or SiC, a dry etch process with tetramethylammonium hydroxide (TMAH), ammonium hydroxide (NH₄OH), or the like may be used to remove the first nanostructures 52.

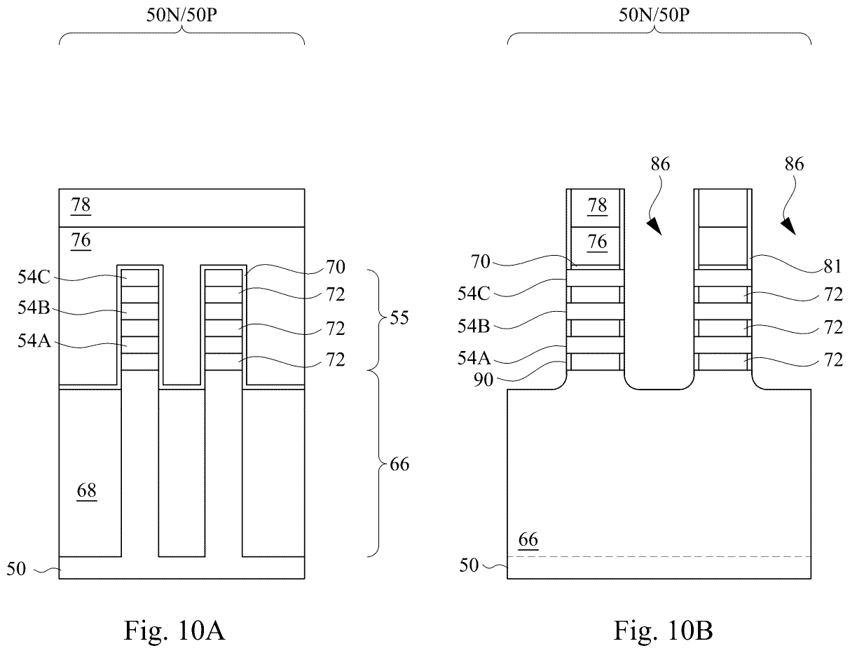

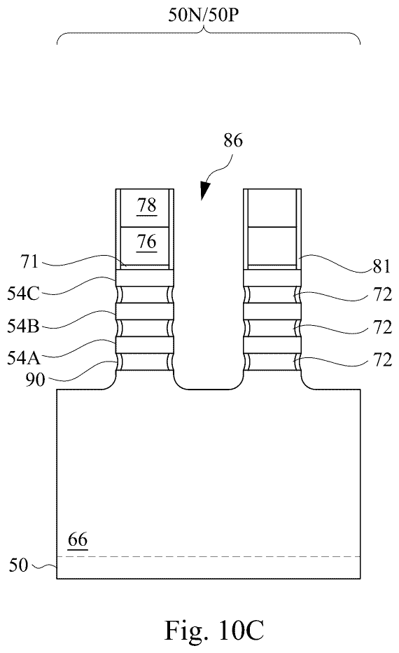

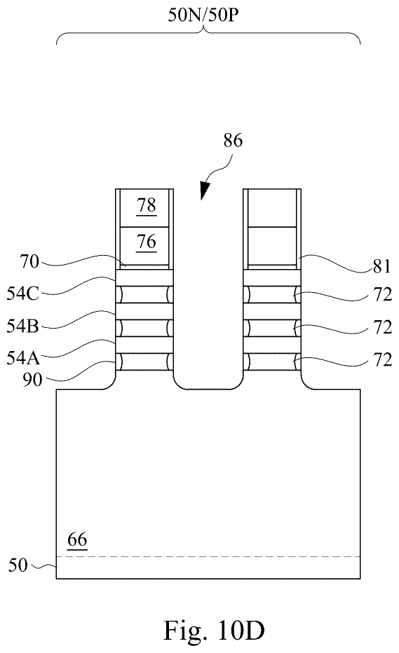

Subsequently, a sacrificial material layer 71 is deposited in the first recesses 86 and spaces where the first nanostructures 52 were removed. The sacrificial material layer 71 may be deposited by a conformal deposition process, such as CVD, ALD, or the like. The sacrificial material layer may comprise an insulating material such as silicon oxide (e.g., SiO₂), or the like that can be selectively etched from the second nanostructures 54. In FIGS. 9A and 9B, the sacrificial material layer 71 may then be etched to form the sacrificial material 72. The etching may be isotropic or anisotropic. For example, the sacrificial material layer may be etched by a wet etch process using diluted HF, or the like as an etchant. In some embodiments, the etching is performed until sidewalls of the sacrificial material 72 is recessed past sidewalls of the nanostructures 54. Although sidewalls of sacrificial material 72 are illustrated as being straight in FIG. 9B, the sidewalls may be concave or convex (see e.g., FIG. 10C).

Replacing the first nanostructures 52 with the sacrificial material 72 may provide advantages. For example, in subsequent source/drain formation steps, one or more high temperature processes may be performed to, for example, activate the dopants in the source/drain regions. When the material of the first nanostructures 52 (e.g., SiGe) is exposed to high temperatures, germanium intermixing and increased roughness at an interfaces between the nanostructures 52 and 54 may result. Such manufacturing defects may degrade the performance of the resulting transistor devices. For example, when germanium diffuses into the second nanostructures 74, germanium residue may remain in channel regions of the resulting transistor devices, which negatively affects the performance of the channel regions. By replacing the first nanostructures 52 with an insulating material prior to the high temperature processes (e.g., source/drain annealing), manufacturing defects can be reduced and device performance can be improved (e.g., increased current drive, reduced capacitance, and improved short channel effect).

In FIGS. 10A and 10B, inner spacers 90 are formed in the first recesses 86 on the sidewalls of the sacrificial material 72. The inner spacers 90 act as isolation features between subsequently formed source/drain regions and a gate structure. As will be discussed in greater detail below, source/drain regions will be formed in the first recesses 86, while the sacrificial material 72 will be replaced with corresponding gate structures. The inner spacers 90 may also be used to prevent damage to subsequently formed source/drain regions by subsequent etching processes, such as etching processes used to form gate structures.

The inner spacers 90 may be formed by depositing an inner spacer layer (not separately illustrated) over the structures illustrated in FIGS. 9A and 9B. The inner spacer layer may be deposited by a conformal deposition process, such as CVD, ALD, or the like. The inner spacer layer may comprise a material such as silicon nitride or silicon oxynitride, although any suitable material, such as low-dielectric constant (low-k) materials having a k-value less than about 3.5, may be utilized. The inner spacer layer may then be anisotropically etched to form the inner spacers 90. The inner spacer layer may be etched by an anisotropic etching process, such as RIE, NBE, or the like.

Although outer sidewalls of the inner spacers 90 are illustrated as being flush with sidewalls of the second nanostructures 54, the outer sidewalls of the inner spacers 90 may extend beyond or be recessed from sidewalls of the second nanostructures 54 (see e.g., FIG. 10C). Moreover, although the outer sidewalls of the inner spacers 90 are illustrated as being straight in FIG. 10B, the outer sidewalls of the inner spacers 90 may be concave or convex. As an example, FIG. 10C illustrates an embodiment in which sidewalls of the sacrificial material 72 are concave, outer sidewalls of the inner spacers 90 are concave, and the inner spacers 90 are recessed from sidewalls of the second nanostructures 54. Other configurations are also possible. For example, FIG. 10D illustrates an embodiment in which sidewalls of the sacrificial material 72 are concave, outer sidewalls of the inner spacers 90 are straight, and the inner spacers 90 are flush with sidewalls of the second nanostructures 54.

In FIGS. 11A-11F, epitaxial source/drain regions 92 are formed in the first recesses 86. In some embodiments, the source/drain regions 92 may exert stress on the second nanostructures 54 in the n-type region 50N and/or on the first nanostructures 52 in the p-type region 50P, thereby improving performance. As illustrated in FIG. 11B, the epitaxial source/drain regions 92 are formed in the first recesses 86 such that each dummy gate 76 is disposed between respective neighboring pairs of the epitaxial source/drain regions 92. In some embodiments, the gate spacers 81 are used to separate the epitaxial source/drain regions 92 from the dummy gates 76 and the inner spacers 90 are used to separate the epitaxial source/drain regions 92 from the sacrificial material 72 by an appropriate lateral distance so that the epitaxial source/drain regions 92 do not short out with subsequently formed gates of the resulting nano-FETs.

The epitaxial source/drain regions 92 in the n-type region 50N, e.g., the NMOS region, may be formed by masking the p-type region 50P, e.g., the PMOS region. Then, the epitaxial source/drain regions 92 are epitaxially grown in the first recesses 86 in the n-type region 50N. The epitaxial source/drain regions 92 may include any acceptable material appropriate for n-type nano-FETs. For example, if the second nanostructures 54 are silicon, the epitaxial source/drain regions 92 in the n-type region 50N may include materials exerting a tensile strain on the second nanostructures 54, such as silicon, silicon carbide, phosphorous doped silicon carbide, silicon phosphide, or the like.

The epitaxial source/drain regions 92 in the p-type region 50P, e.g., the PMOS region, may be formed by masking the n-type region 50N, e.g., the NMOS region. Then, the epitaxial source/drain regions 92 are epitaxially grown in the first recesses 86 in the p-type region 50P. The epitaxial source/drain regions 92 may include any acceptable material appropriate for p-type nano-FETs. For example, if the second nanostructures 54 are silicon, the epitaxial source/drain regions 92 in the p-type region 50P may include materials exerting a compressive strain on the second nanostructures 54, such as silicon-germanium, boron doped silicon-germanium, germanium, germanium tin, or the like.

The epitaxial source/drain regions 92, the second nanostructures 54, and/or the substrate 50 may be implanted with dopants to form source/drain regions, similar to the process previously discussed for forming lightly-doped source/drain regions, followed by an anneal. The source/drain regions may have an impurity concentration of between about 1×10¹⁹ atoms/cm³ and about 1×10²¹ atoms/cm³. The n-type and/or p-type impurities for source/drain regions may be any of the impurities previously discussed. In some embodiments, the epitaxial source/drain regions 92 may be in situ doped during growth.

As a result of the epitaxy processes used to form the epitaxial source/drain regions 92 in the n-type region 50N and the p-type region 50P, upper surfaces of the epitaxial source/drain regions 92 have facets which expand laterally outward beyond sidewalls of the nanostructures 55. In some embodiments, these facets cause adjacent epitaxial source/drain regions 92 of a same nano-FET to merge as illustrated by FIG. 11C. In other embodiments, adjacent epitaxial source/drain regions 92 remain separated after the epitaxy process is completed as illustrated by FIG. 11D. In the embodiments illustrated in FIGS. 11C and 11D, the fin spacers 83 may be formed on top surfaces of the STI regions 68, thereby blocking the epitaxial growth. In some other embodiments, the fin spacers 83 may cover portions of the sidewalls of the nanostructures 55 further blocking the epitaxial growth. In some other embodiments, the fin spacers 83 may be omitted entirely, and the epitaxially grown region may extend to the top surface of the STI regions 68.

The epitaxial source/drain regions 92 may comprise one or more semiconductor material layers. For example, the epitaxial source/drain regions 92 may comprise a first semiconductor material layer 92A, a second semiconductor material layer 92B, and a third semiconductor material layer 92C. Any number of semiconductor material layers may be used for the epitaxial source/drain regions 92. Each of the first semiconductor material layer 92A, the second semiconductor material layer 92B, and the third semiconductor material layer 92C may be formed of different semiconductor materials and may be doped to different dopant concentrations. In some embodiments, the first semiconductor material layer 92A may have a dopant concentration less than the second semiconductor material layer 92B and greater than the third semiconductor material layer 92C. In embodiments in which the epitaxial source/drain regions 92 comprise three semiconductor material layers, the first semiconductor material layer 92A may be deposited, the second semiconductor material layer 92B may be deposited over the first semiconductor material layer 92A, and the third semiconductor material layer 92C may be deposited over the second semiconductor material layer 92B.

In some embodiments, the first semiconductor material layer 92A may include two distinct layers (not separately labeled). For example, the first semiconductor material layer 92A may include an initial layer L₀ and a primary layer L₁. The initial layer L₀ may comprise boron-doped silicon (Si:B) or boron-doped silicon germanium (Si₁₋ₓGeₓ:B, wherein 0<x<0.1) with a boron concentration of up to 1.0E21 atoms/cm³ and be formed at relatively high temperatures ranging from 600° C. to 800° C. over exposed semiconductor material (e.g., the nanostructures 54 and the substrate 50). The primary layer L₁ may comprise boron-doped silicon germanium (Si₁₋ₓGeₓ:B, wherein 0.1≤x≤0.4) with a boron concentration of up to 7.0E20 atoms/cm³ and be formed at lower temperatures ranging from 400° C. to 600° C. over exposed semiconductor material (e.g., the initial layer L₀).

Further, the second semiconductor material layer 92B and the third semiconductor material layer 92C may sometimes be discussed collectively or separately. The second semiconductor material layer 92B is sometimes referred to as a secondary layer L₂, and the third semiconductor material layer 92C is sometimes referred to as a tertiary layer L₃. The secondary layer L₂ may comprise boron-doped silicon germanium (Si₁₋ₓGeₓ:B, wherein 0.4≤x≤0.9) with a boron concentration of greater than or equal to 7.0E20 atoms/cm³ and be formed at lower temperatures ranging from 400° C. to 600° C. over exposed semiconductor material (e.g., the primary layer L₁). The tertiary layer L₃ may be formed within the parameters described above in connection with the secondary layer L₂, albeit with lower dopant concentrations than the other layers.

FIGS. 11E and 11F illustrate additional views of the formation of exemplary epitaxial source/drain regions 92, in accordance with some embodiments. In some embodiments, the illustrated epitaxial source/drain regions 92 may be components of PMOS transistors (e.g., p-type nano-FETs). Note that each top figure depicts a side cross-sectional view similar to FIGS. 11C and 11D along with some components of the foreground or background (e.g., outlined with dashed lines) for context. Each bottom figure depicts a plan view at reference cross-section D-D′ labeled in the corresponding top figure.

FIG. 11E shows an epitaxial source/drain region 92_{N} of one or more narrow channel nano-FETs (e.g., narrow nanostructures 54_{N} and narrow fins 66_{N}), and FIG. 11F shows an epitaxial source/drain region 92_{W} of one or more wide channel nano-FETs (e.g., wide nanostructures 54_{W} and wide fins 66_{W}). As provided in the figures, the terms “narrow” and “wide” may be indicative of widths W (e.g., width W_{N} and width W_{W}, respectively) of the fins 66 of the respective nano-FETs (e.g., narrow channel regions 54_{N} and wide channel regions 54_{W}, respectively, of the nanostructures 54). For the sake of simplicity, the respective epitaxial source/drain regions 92 may be referred to as the narrow epitaxy 92_{N} and the wide epitaxy 92_{W}.

In some embodiments, the narrow epitaxy 92_{N} is formed along nanostructures 54_{N} with a width W_{N} ranging from 5 nm to 20 nm, and the wide epitaxy 92_{W} is formed along nanostructures 54_{W} with a width W_{W} ranging from 60 nm to 100 nm. In addition, a distance D_{N} between adjacent dummy gates 76_{N} may be substantially equal to a distance D_{W} between adjacent dummy gates 76_{W} (e.g., a substantially same pitch). For example, the distances D_{N} and D_{W} may range from 10 nm to 50 nm or range from the width W_{N} to the width W_{W}. In addition, in embodiments in which the substrate 50 has a (110) orientation, the fins 66_{N} may be parallel or skew perpendicular with the fins 66_{W} and the dummy gates 76_{N} may be parallel or skew perpendicular with the dummy gates 76_{W}. As illustrated, the narrow epitaxy 92_{N} and the wide epitaxy 92_{W} may be grown simultaneously, wherein the wide epitaxy 92_{W} has an overall faster rate of growth than the narrow epitaxy 92_{N}. The formation process may be terminated when a raised height h_{W} of the wide epitaxy 92_{W} is about the same or greater than a raised height h_{N} of the narrow epitaxy 92_{N}. Note that the raised heights h_{N}/h_{W} may be measured from the underlying fins 66 (e.g., at a point on the epitaxial source/drain region 92 that is most proximal to the substrate 50), however, any suitable reference point may be used to identify the desired heights. As such, a raised height difference Δh (e.g., h_{W}−h_{N}) may range from 0 nm to 60 nm.

As further illustrated, the epitaxial source/drain regions 92 may form in a variety of shapes. For example, the general shapes provided in FIGS. 11E and 11F differ from the general shapes provided in FIGS. 11C and 11D. Referring to FIGS. 11E and 11F, the epitaxial material may grow with certain facets having a flatter angle, such as a 35.3° angle, with respect to the horizontal (e.g., a major plane of the substrate 50). This flatter angle affords greater control over formation of the epitaxial source/drain regions 92 to achieve desired raised heights h_{N}/h_{W} of each type (e.g., a desired raised height difference Δh).

Advantages are achieved by the above-described process for forming the epitaxial source/drain regions 92. The geometries of the narrow epitaxy 92_{N} and the wide epitaxy 92_{W} facilitate certain growth rates throughout the process, which allow for greater control of the final dimensions of the respective epitaxial source/drain regions 92. For example, a growth rate of the first semiconductor material layer 92A_{N} of the narrow epitaxy 92_{N} would ordinarily be greater than a growth rate of the first semiconductor material layer 92A_{W} of the wide epitaxy 92_{W} due to less circulation within the first recess 86_{W} of the wide epitaxy 92_{W} caused by W_{W}>W^{N} and D_{W}≈D_{N}. In particular, this results in less circulation of deposition precursors to reach the sidewalls of the nanostructures 54_{W}. However, as illustrated in the bottom figures, the trapezoidal growth patterns eventually become triangular patterns for the first semiconductor material layer 92A_{N} of the narrow epitaxy 92_{N} or merging trapezoidal patterns for the first semiconductor material layer 92A_{W} of the wide epitaxy 92_{W}. In some embodiments, when the triangular patterns are formed, the growth rate of the first semiconductor material layer 92A_{N} slows down substantially to be less than the growth rate of the first semiconductor material layer 92A_{W}. As a result, a ratio of a surface area of the first semiconductor material layer 92A_{W} to a surface area of the first semiconductor material layer 92A_{N} is greater than a ratio of the corresponding widths (e.g., W_{W}:W_{N}). Note that FIG. 11B illustrates the discrete first semiconductor material layers 92A_{N} of the narrow epitaxies 92_{N} (e.g., FIG. 11E) and provides dashed outlines for the first semiconductor material layers 92A_{W} of the wide epitaxies 92_{W} (e.g., FIG. 11F).

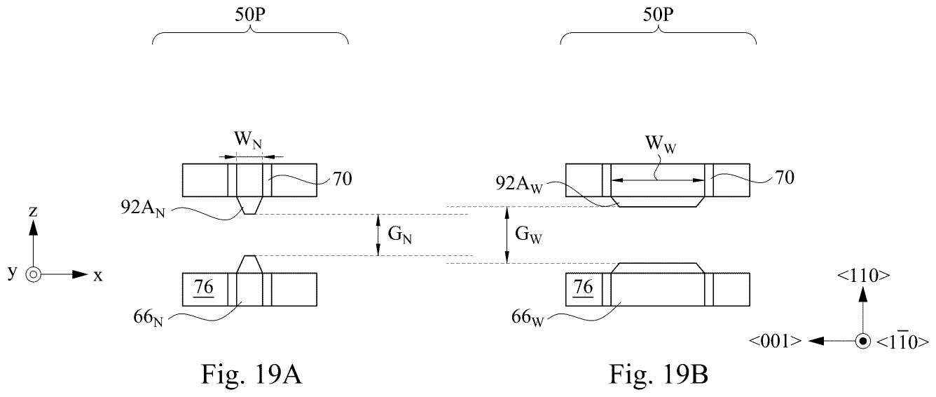

Moreover, growth rates of the respective second and third semiconductor material layers 92B/92C (referred to in this portion of the discussion as the second semiconductor material layers 92B for the sake of simplicity) may also be affected by the associated geometries as well as by the sizes of the respective first semiconductor material layers 92A. For example, a growth rate of the second semiconductor material layer 92B_{W} of the wide epitaxy 92_{W} may be greater than a growth rate of the second semiconductor material layer 92B_{N} of the narrow epitaxy 92_{N}. In particular, this occurs because of the disproportionately greater surface area of the first semiconductor material layer 92A_{W}. In addition, the merged growth pattern of the first semiconductor material layer 92A_{W} makes the exposed surface area more accessible by the deposition precursors for continued growth as compared to the initial growth of the first semiconductor material layer 92A_{W}. As a result, after a sufficient duration, the raised height of the wide epitaxy 92_{W} may equal and then eventually surpass the raised height of the narrow epitaxy 92_{N}, as illustrated in the figures. See FIGS. 19A-24E and accompanying discussion below for additional discussion of the growth processes for the narrow epitaxy 92_{N} and the wide epitaxy 92_{W}.

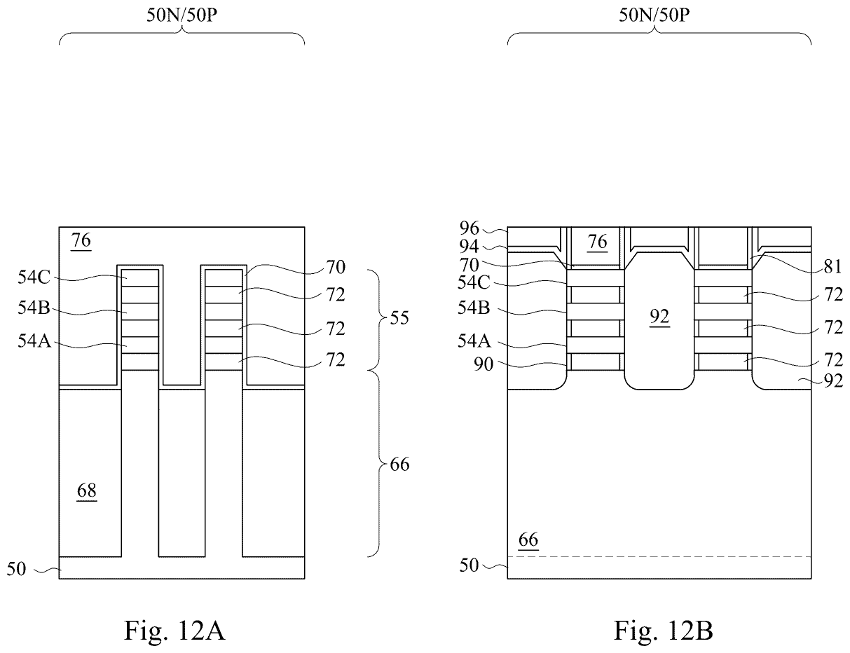

In FIGS. 12A and 12B, a first interlayer dielectric (ILD) 96 is deposited over the structure illustrated in FIGS. 11A and 11B, respectively. The first ILD 96 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) 94 is disposed between the first ILD 96 and the epitaxial source/drain regions 92, the masks 78, and the gate spacers 81. The CESL 94 may comprise a dielectric material, such as, silicon nitride, silicon oxide, silicon oxynitride, or the like, having a different etch rate than the material of the overlying first ILD 96.

After the first ILD 96 is deposited, a planarization process, such as a CMP, may be performed to level the top surface of the first ILD 96 with the top surfaces of the dummy gates 76 (as shown) or the masks 78. The planarization process may also remove the masks 78 on the dummy gates 76, and portions of the gate spacers 81 along sidewalls of the masks 78. After the planarization process, top surfaces of the dummy gates 76, the gate spacers 81, and the first ILD 96 are level within process variations. Accordingly, the top surfaces of the dummy gates 76 are exposed through the first ILD 96. In some embodiments, the masks 78 may remain, in which case the planarization process levels the top surface of the first ILD 96 with top surface of the masks 78 and the gate spacers 81.

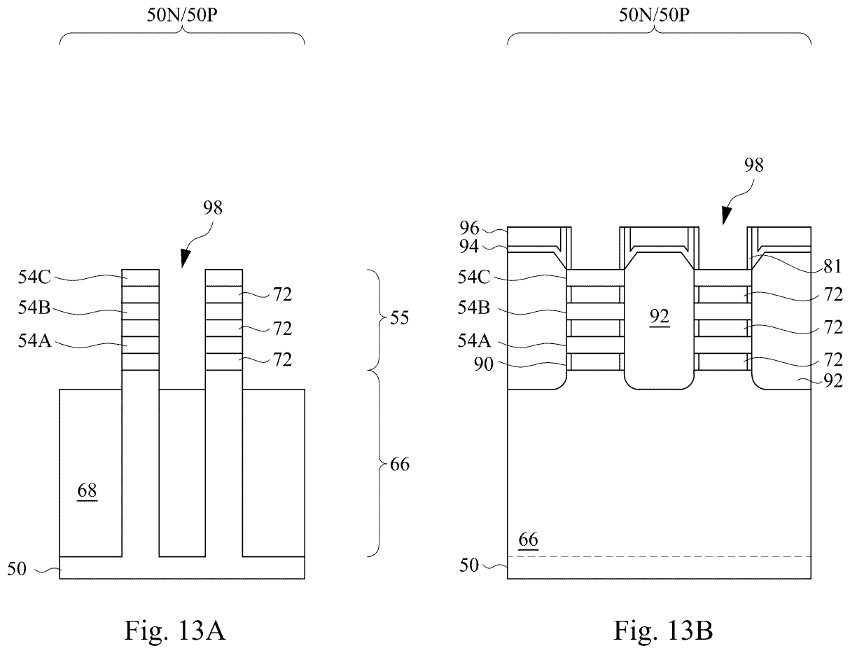

In FIGS. 13A and 13B, the dummy gates 76, and the masks 78 if present, are removed in one or more etching steps, so that second recesses 98 are formed. Portions of the dummy gate dielectrics 70 in the second recesses 98 may also be removed. In some embodiments, the dummy gates 76 and the dummy gate dielectrics 70 are removed by an anisotropic dry etch process. For example, the etching process may include a dry etch process using reaction gas(es) that selectively etch the dummy gates 76 at a faster rate than the first ILD 96 or the gate spacers 81. Each second recess 98 exposes and/or overlies portions of nanostructures 55, which act as channel regions in subsequently completed nano-FETs. Portions of the nanostructures 55 which act as the channel regions are disposed between neighboring pairs of the epitaxial source/drain regions 92. During the removal, the dummy gate dielectrics 70 may be used as etch stop layers when the dummy gates 76 are etched. The dummy gate dielectrics 70 may then be removed after the removal of the dummy gates 76.

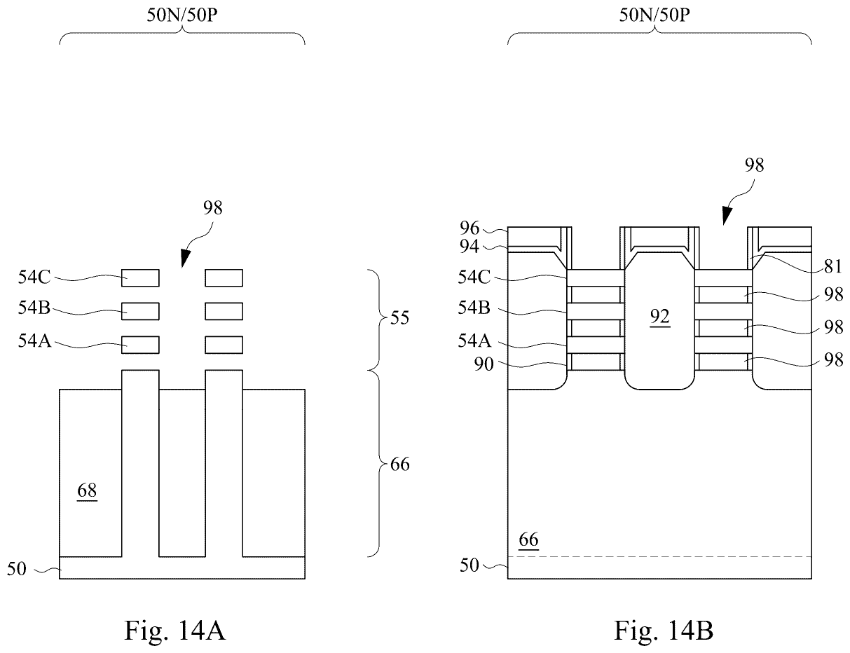

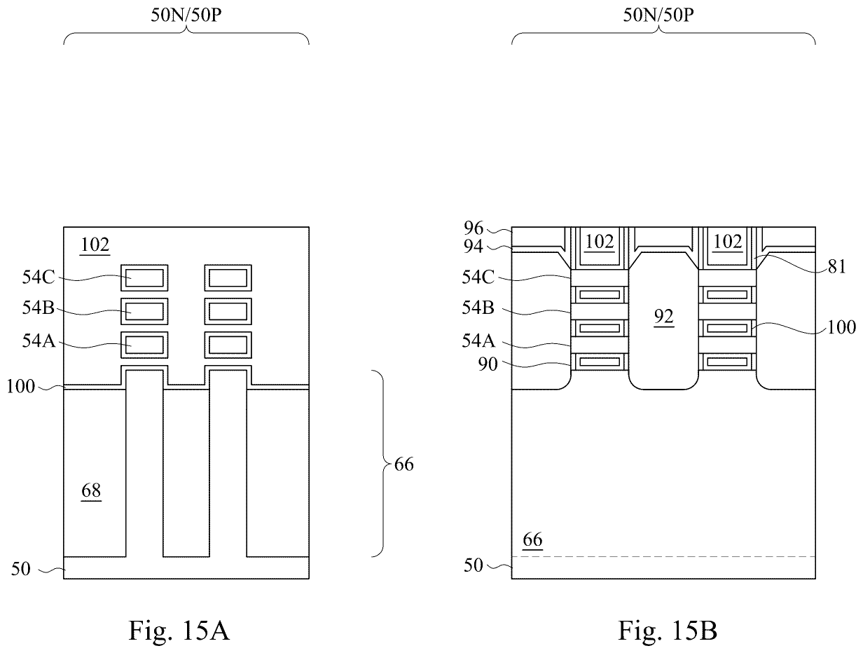

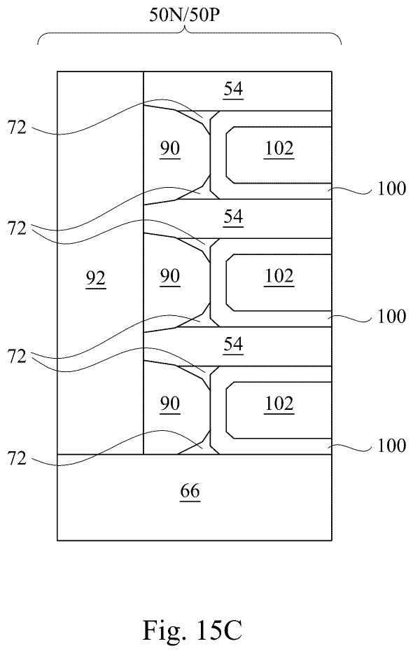

In FIGS. 14A and 14B, the sacrificial material 72 is removed, extending the second recesses 98. Removing the sacrificial material 72 may include performing an isotropic etching process such as wet etching or the like using etchants which are selective to the materials of the sacrificial material 72, while the second nanostructures 54 remain relatively unetched as compared to the sacrificial material 72. The sacrificial material 72 may be completely removed, or a residue of the sacrificial material 72 may remain on sidewalls of the inner spacers in the second recesses 98 (see e.g., FIG. 15C).

In some embodiments, the STI regions 68 may be etched while removing the sacrificial material 72, but the total amount of loss in the STI regions 68 may be reduced by controlling etching parameters (e.g., timing) while removing the sacrificial material 72. In other embodiments, the STI regions 68 may include a hard mask (not separately illustrated) at a top surface to protect the underlying STI regions 68 from etching while patterning and removing the sacrificial material 72. In such embodiments, the hard mask may comprise, for example, a nitride.

In FIGS. 15A-15C, gate dielectric layers 100 and gate electrodes 102 are formed for replacement gates. The gate dielectric layers 100 are deposited conformally in the second recesses 98. The gate dielectric layers 100 may be formed on top surfaces and sidewalls of the substrate 50 and on top surfaces, sidewalls, and bottom surfaces of the second nanostructures 54. The gate dielectric layers 100 may also be deposited on top surfaces of the first ILD 96, the CESL 94, the gate spacers 81, and the STI regions 68.

In accordance with some embodiments, the gate dielectric layers 100 comprise one or more dielectric layers, such as an oxide, a metal oxide, the like, or combinations thereof. For example, in some embodiments, the gate dielectrics may comprise a silicon oxide layer and a metal oxide layer over the silicon oxide layer. In some embodiments, the gate dielectric layers 100 include a high-k dielectric material, and in these embodiments, the gate dielectric layers 100 may have a k value greater than about 7.0, and may include a metal oxide or a silicate of hafnium, aluminum, zirconium, lanthanum, manganese, barium, titanium, lead, and combinations thereof. The structure of the gate dielectric layers 100 may be the same or different in the n-type region 50N and the p-type region 50P. The formation methods of the gate dielectric layers 100 may include molecular-beam deposition (MBD), ALD, PECVD, and the like.

The gate electrodes 102 are deposited over the gate dielectric layers 100, respectively, and fill the remaining portions of the second recesses 98. The gate electrodes 102 may include a metal-containing material such as titanium nitride, titanium oxide, tantalum nitride, tantalum carbide, cobalt, ruthenium, aluminum, tungsten, combinations thereof, or multi-layers thereof. For example, although single layer gate electrodes 102 are illustrated in FIGS. 15A-15C, the gate electrodes 102 may comprise any number of liner layers, any number of work function tuning layers, and a fill material. Any combination of the layers which make up the gate electrodes 102 may be deposited in the n-type region 50N between adjacent ones of the second nanostructures 54 and between the second nanostructure 54A and the substrate 50, and may be deposited in the p-type region 50P between adjacent ones of the first nanostructures 52.

The formation of the gate dielectric layers 100 in the n-type region 50N and the p-type region 50P may occur simultaneously such that the gate dielectric layers 100 in each region are formed from the same materials, and the formation of the gate electrodes 102 may occur simultaneously such that the gate electrodes 102 in each region are formed from the same materials. In some embodiments, the gate dielectric layers 100 in each region may be formed by distinct processes, such that the gate dielectric layers 100 may be different materials and/or have a different number of layers, and/or the gate electrodes 102 in each region may be formed by distinct processes, such that the gate electrodes 102 may be different materials and/or have a different number of layers. Various masking steps may be used to mask and expose appropriate regions when using distinct processes.

After the filling of the second recesses 98, a planarization process, such as a CMP, may be performed to remove the excess portions of the gate dielectric layers 100 and the material of the gate electrodes 102, which excess portions are over the top surface of the first ILD 96. The remaining portions of material of the gate electrodes 102 and the gate dielectric layers 100 thus form replacement gate structures of the resulting nano-FETs. The gate electrodes 102 and the gate dielectric layers 100 may be collectively referred to as “gate structures.”

FIG. 15C illustrates a detailed view of various elements of FIG. 15B, including the epitaxial source/drain regions 92, the gate dielectric layers 100, the gate electrodes 102, the second nanostructures 54, and the inner spacers 90. In some embodiments, as illustrated by FIG. 15C, a residue of the sacrificial material 72 may remain on the inner spacers 90, such as between the inner spacers 90 and the gate dielectric layers 100/gate electrodes 102. For example, the sacrificial material 72 may not be fully removed, and the gate dielectric layers 100 may be formed on the remaining sacrificial material 72. Because the sacrificial material 72 is an insulating material (e.g., silicon oxide), the remaining residue may not significantly impact the electrical performance of the resulting device.

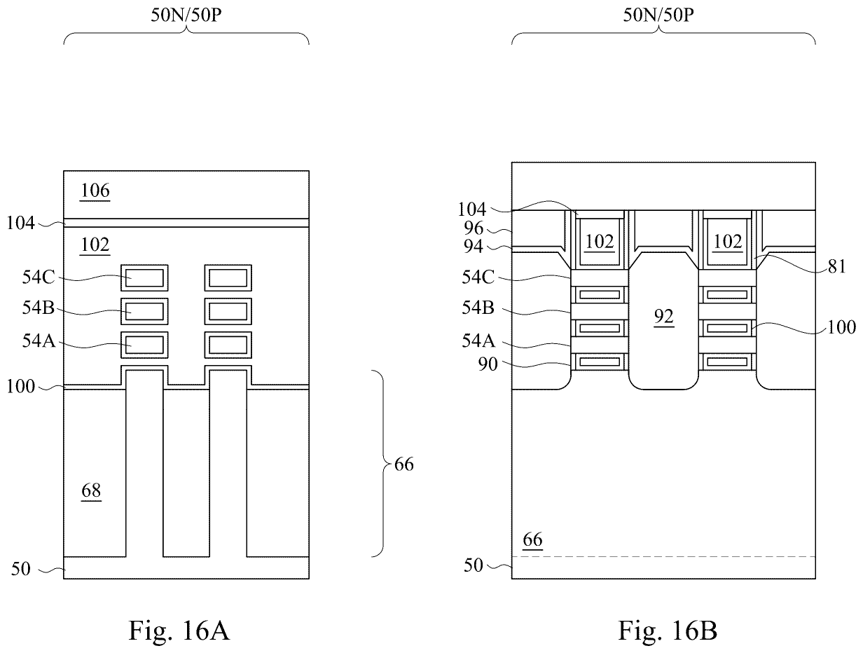

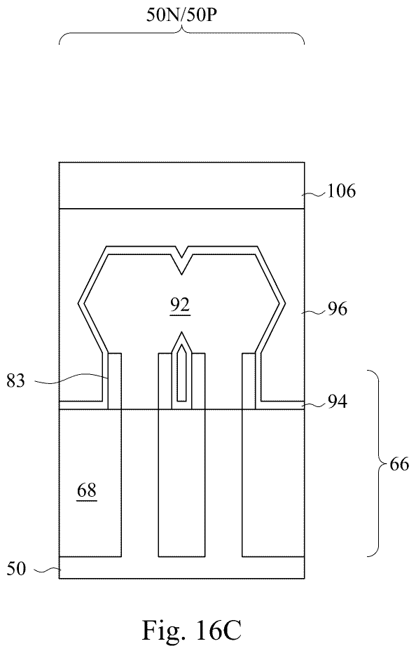

In FIGS. 16A-16C, the gate structure (including the gate dielectric layers 100 and the corresponding overlying gate electrodes 102) is recessed, so that a recess is formed directly over the gate structure and between opposing portions of gate spacers 81. A gate mask 104 comprising one or more layers of dielectric material, such as silicon nitride, silicon oxynitride, or the like, is filled in the recess, followed by a planarization process to remove excess portions of the dielectric material extending over the first ILD 96. Subsequently formed gate contacts (such as the gate contacts 114, discussed below with respect to FIGS. 18A-18C) penetrate through the gate mask 104 to contact the top surface of the recessed gate electrodes 102.

As further illustrated by FIGS. 16A-16C, a second ILD 106 is deposited over the first ILD 96 and over the gate mask 104. In some embodiments, the second ILD 106 is a flowable film formed by FCVD. In some embodiments, the second ILD 106 is formed of a dielectric material such as PSG, BSG, BPSG, USG, or the like, and may be deposited by any suitable method, such as CVD, PECVD, or the like.

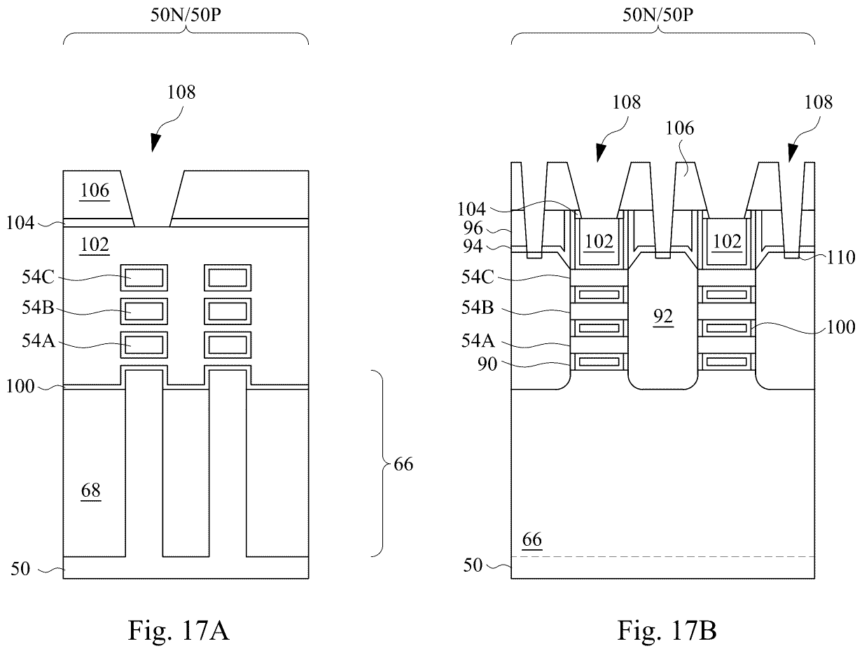

In FIGS. 17A-17C, the second ILD 106, the first ILD 96, the CESL 94, and the gate masks 104 are etched to form third recesses 108 exposing surfaces of the epitaxial source/drain regions 92 and/or the gate structure. The third recesses 108 may be formed by etching using an anisotropic etching process, such as RIE, NBE, or the like. In some embodiments, the third recesses 108 may be etched through the second ILD 106 and the first ILD 96 using a first etching process; may be etched through the gate masks 104 using a second etching process; and may then be etched through the CESL 94 using a third etching process. A mask, such as a photoresist, may be formed and patterned over the second ILD 106 to mask portions of the second ILD 106 from the first etching process and the second etching process. In some embodiments, the etching process may over-etch, and therefore, the third recesses 108 extend into the epitaxial source/drain regions 92 and/or the gate structure, and a bottom of the third recesses 108 may be level with (e.g., at a same level, or having a same distance from the substrate), or lower than (e.g., closer to the substrate) the epitaxial source/drain regions 92 and/or the gate structure. Although FIG. 17B illustrate the third recesses 108 as exposing the epitaxial source/drain regions 92 and the gate structure in a same cross section, in various embodiments, the epitaxial source/drain regions 92 and the gate structure may be exposed in different cross-sections, thereby reducing the risk of shorting subsequently formed contacts.

After the third recesses 108 are formed, silicide regions 110 are formed over the epitaxial source/drain regions 92. In some embodiments, the silicide regions 110 are formed by first depositing a metal (not shown) capable of reacting with the semiconductor materials of the underlying epitaxial source/drain regions 92 (e.g., silicon, silicon germanium, germanium) to form silicide or germanide regions. For example, metals such as nickel, cobalt, titanium, tantalum, platinum, tungsten, other noble metals, other refractory metals, rare earth metals or their alloys, may be used. The metal may be deposited over the exposed portions of the epitaxial source/drain regions 92. A thermal annealing process may then be utilized to form the silicide regions 110. The un-reacted portions of the deposited metal are then removed, e.g., by an etching process. Although silicide regions 110 are referred to as silicide regions, silicide regions 110 may also be germanide regions, or silicon germanide regions (e.g., regions comprising silicide and germanide). In an embodiment, the silicide region 110 comprises TiSi, and has a thickness in a range between about 2 nm and about 10 nm.

Next, in FIGS. 18A-18E, contacts 112 and 114 (may also be referred to as contact plugs) are formed in the third recesses 108. The contacts 112 and 114 may each comprise one or more layers, such as barrier layers, diffusion layers, and fill materials. For example, in some embodiments, the contacts 112 and 114 each include a barrier layer and a conductive material, and are electrically coupled to the underlying conductive feature (e.g., gate structure 102 and/or silicide region 110 in the illustrated embodiment). The contacts 114 are electrically coupled to the gate structure 102 and may be referred to as gate contacts, and the contacts 112 are electrically coupled to the silicide regions 110 and may be referred to as source/drain contacts. The barrier layer may include titanium, titanium nitride, tantalum, tantalum nitride, or the like. The conductive material may be copper, a copper alloy, silver, gold, tungsten, cobalt, aluminum, nickel, or the like. A planarization process, such as a CMP, may be performed to remove excess material from a surface of the second ILD 106.

FIGS. 18D and 18E illustrate the contacts 112 formed over the exemplary epitaxial source/drain regions 92 of FIGS. 11E and 11F, respectively. Each top figure depicts a side cross-sectional view similar to FIG. 18C along with some components of the foreground or background (e.g., outlined with dashed lines) for context. Each bottom figure depicts a plan view at reference cross-section D-D′ labeled in the corresponding top figure.

As illustrated, the embodiments described above ensure that the wide epitaxy 92_{W} grows to a sufficient raised height for the contact 112_{W} to make adequate contact. For example, instead, if the raised height of the wide epitaxy 92_{W} were lower than the raised height of the narrow epitaxy 92_{N} (e.g., the raised height difference Δh being negative), then the contact 112_{W} may have a relatively small contact area with the relatively large wide epitaxy 92_{W}. Such a small contact area could provide reduced performance and reliability for this portion of the integrated circuit. As such, the raised height difference Δh being positive will ensure that any depth of the contact 112_{N} to the narrow epitaxy 92_{N} would be adequate for the contact 112_{W} to the wide epitaxy 92_{W}. In some embodiments, the contact area between the contact 112_{W} and the wide epitaxy 92_{W} may be greater than or equal to the contract area between the contact 112_{N} and the narrow epitaxy 92_{N}.

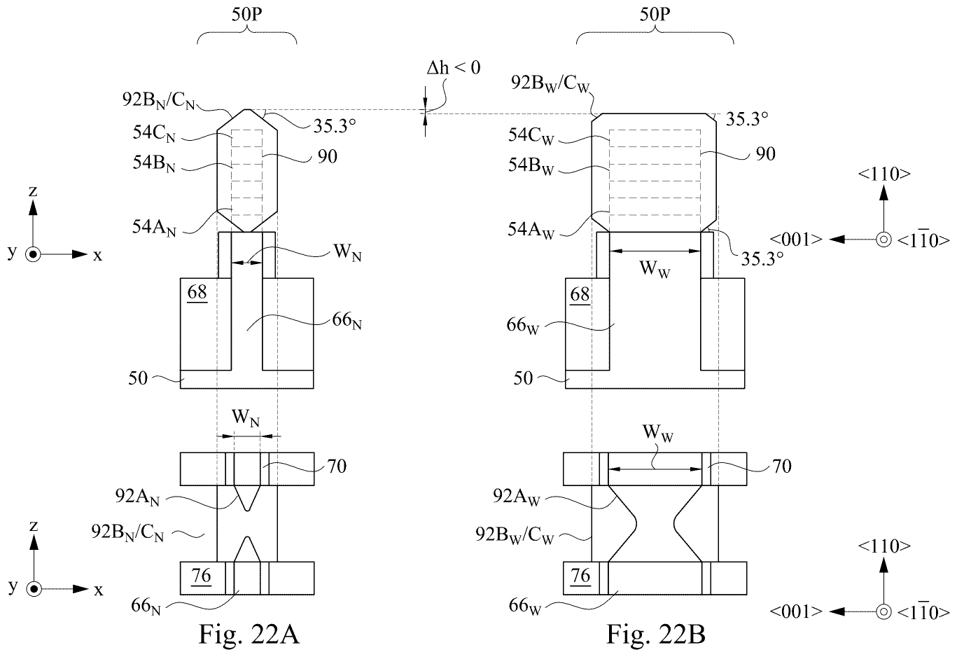

FIGS. 19A-24B illustrate the growth processes for the narrow epitaxy 92_{N} and the wide epitaxy 92_{W} (see FIGS. 11E and 11F) of various epitaxial source/drain regions 92, in accordance with some embodiments. FIGS. 19A-21B include plan view cross-sections showing the formation of the respective first semiconductor material layers 92A. FIGS. 22A-24B include side views and plan view cross-sections showing the formation of the respective second and third semiconductor material layers 92B/92C (referred to in this portion of the discussion as the second semiconductor material layers 92B for the sake of simplicity).

In FIGS. 19A and 19B, at an initial stage, an initial growth rate for the first semiconductor material layer 92A_{N} of the narrow epitaxy 92_{N} may be greater than an initial growth rate for the first semiconductor material layer 92A_{W} of the wide epitaxy 92_{W} for similar reasons as discussed previously. In particular, deposition precursor gases may more readily reach and circulate between the fins 66_{N} as compared to the fins 66_{W}. This disparity results in a relative dilution of the deposition precursors at the fins 66_{W} and the nanostructures 54_{W}, thereby resulting in a slower growth rate. As a result, after the initial stage, a gap G_{W} between opposing first semiconductor material layers 92A_{W} is greater than a gap G_{N} between opposing first semiconductor material layers 92A_{N}.

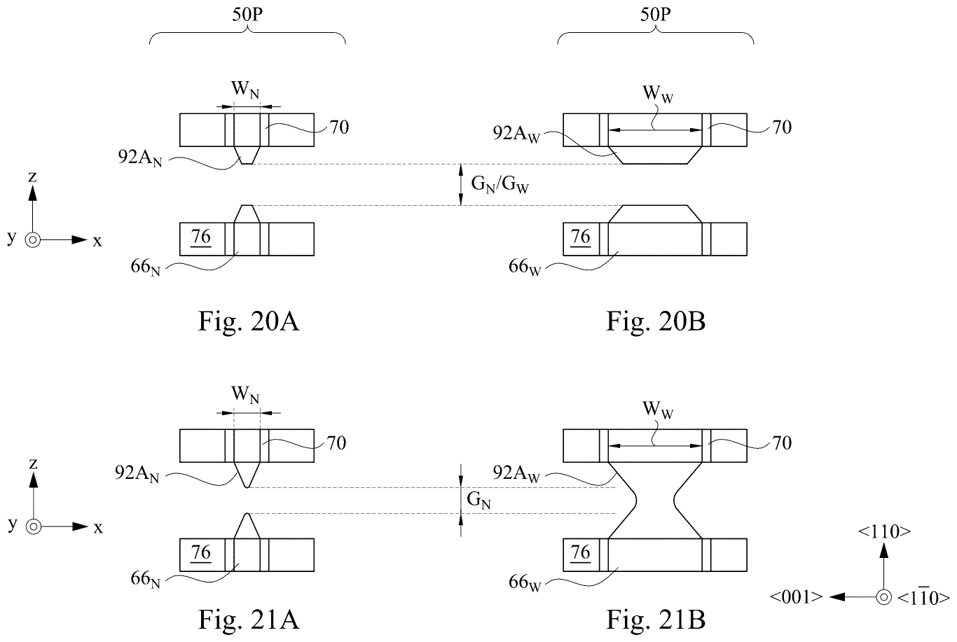

In FIGS. 20A and 20B, at an intermediary stage, an intermediary growth rate for the first semiconductor material layer 92A_{W} of the wide epitaxy 92_{W} may become the same or become greater than an intermediary growth rate for the first semiconductor material layer 92A_{N} of the narrow epitaxy 92_{N}. In particular, a larger exposed surface area of the first semiconductor material layer 92A_{W} may facilitate an increasing growth rate that counterweighs the lower circulation of the deposition precursor gases between the fins 66_{W}. This may result in the growth of the first semiconductor material layer 92A_{W} beginning to catch up with (and perhaps surpass) the growth of the first semiconductor material layer 92A_{N}. As a result, after the intermediary stage, the gap G_{N} may be substantially the same as or greater than the gap G_{W}.

In FIGS. 21A and 21B, at a final stage, a final growth rate for the first semiconductor material layer 92A_{W} of the wide epitaxy 92_{W} may be greater than a final growth rate for the first semiconductor material layer 92A_{N} of the narrow epitaxy 92_{N} for similar reasons as discussed previously. In particular, the growth rate of the first semiconductor material layer 92A_{N} slows as the trapezoidal growth pattern becomes a triangular growth pattern, while the growth rate of the first semiconductor material layer 92A_{W} may continue increasing or remain relatively constant. This disparity results in opposing trapezoidal growth patterns of the first semiconductor material layer 92A_{W} eventually meeting and merging with one another. As a result, after the final stage, the gap G_{N} between opposing first semiconductor material layers 92A_{N} remains (albeit smaller than before) and is, therefore, greater than the gap G_{W} which no longer exists. In some embodiments, the gap G_{N} may be up to 10 nm.

In FIGS. 22A and 22B, at an initial stage, an initial growth rate for the second semiconductor material layer 92B_{N} of the narrow epitaxy 92_{N} may be greater than an initial growth rate for the second semiconductor material layer 92B_{W} of the wide epitaxy 92_{W} for similar reasons as discussed previously. In particular, the smaller size of the narrow epitaxy 92_{N} allows for faster growth than the larger size of the wide epitaxy 92_{W}. As a result, after the initial stage, a raised height of the second semiconductor material layer 92B_{N} is greater than a raised height of the second semiconductor material layer 92B_{W}, such that the raised height difference Δh is negative.

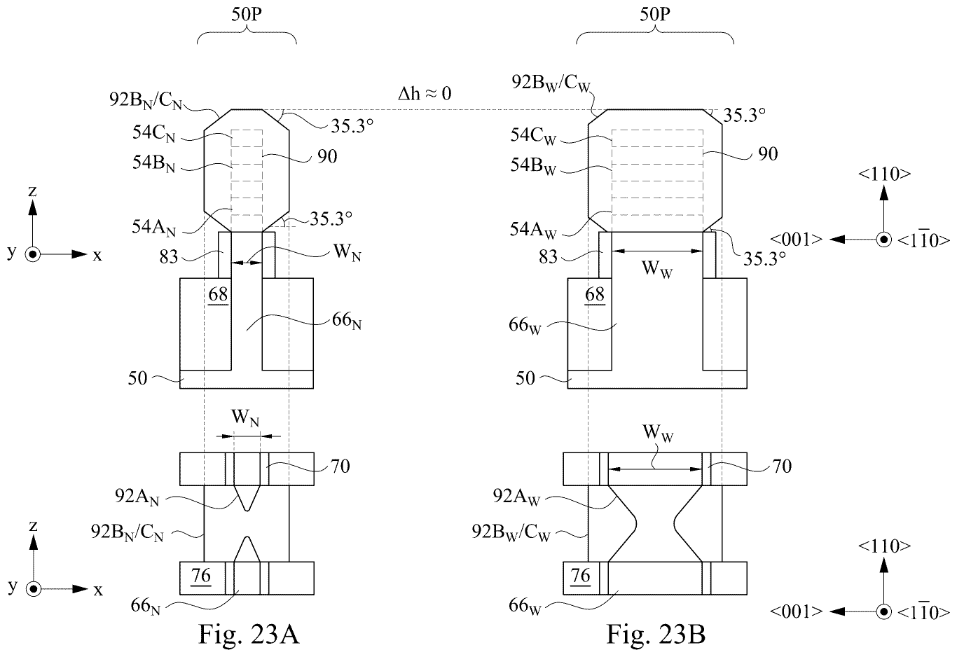

In FIGS. 23A and 23B, at an intermediary stage, an intermediary growth rate for the second semiconductor material layer 92B_{W} of the wide epitaxy 92_{W} may become the same or become greater than an intermediary growth rate for the second semiconductor material layer 92B_{N} of the narrow epitaxy 92_{N}. In particular, a larger exposed surface area of the second semiconductor material layer 92B_{W} may facilitate an increasing growth rate that counterweighs the larger size of the wide epitaxy 92_{W} as compared to the smaller size of the narrow epitaxy 92_{N}. In addition, this effect may be amplified by an upper portion of the narrow epitaxy 92_{N} becoming narrower and approaching a triangular shape at a disproportionately faster rate than an upper portion of the wide epitaxy 92_{W}. As a result, the raised height of the second semiconductor material layer 92B_{W} may be close to, substantially the same as, or greater than the raised height of the second semiconductor material layer 92B_{N}, such that the raised height difference Δh becomes substantially zero.

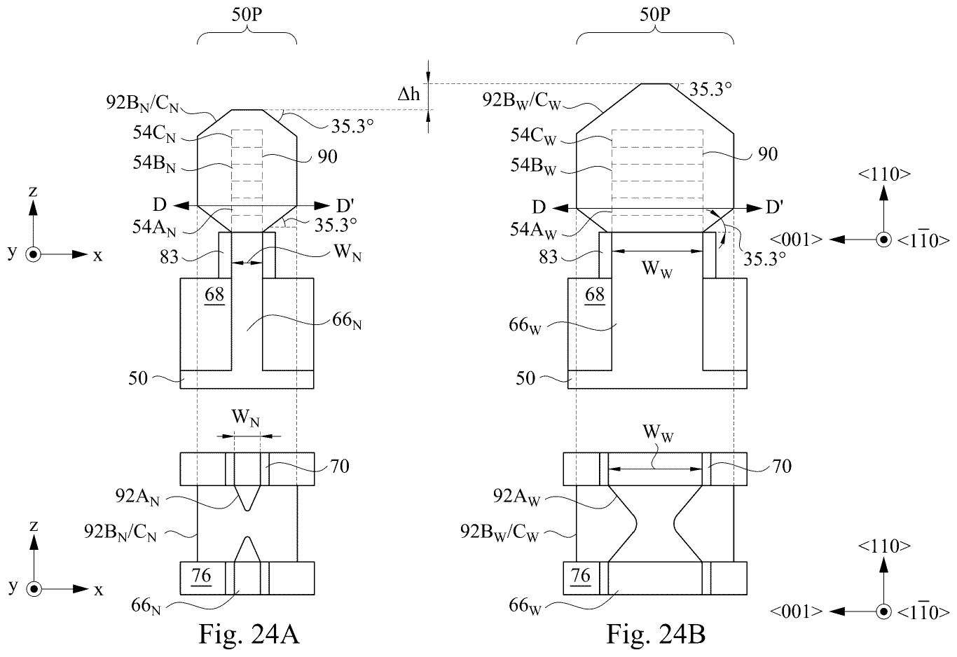

In FIGS. 24A and 24B, at a final stage, a final growth rate for the second semiconductor material layer 92B_{W} of the wide epitaxy 92_{W} may be greater than a final growth rate for the second semiconductor material layer 92B_{N} of the narrow epitaxy 92_{N} for similar reasons as discussed previously. In particular, the growth rate of the second semiconductor material layer 92B_{N} continues to slow as the upper portion increasingly approaches a triangular shape at a disproportionately faster rate than an upper portion of the wide epitaxy 92_{W}. As a result, the raised height of the second semiconductor material layer 92B_{W} may be substantially the same as or greater than the raised height of the second semiconductor material layer 92B_{N}, such that the raised height difference Δh is substantially zero or positive.

Still referring to FIGS. 19A-24B, formation of the epitaxial source/drain regions 92 may be controlled in some ways to result in the height difference Δh being substantially zero (or much closer to zero). For example, the first semiconductor material layer 92A may be completed at an earlier stage before FIGS. 21A and 21B. In particular, formation of the first semiconductor material layer 92A may stop at FIGS. 20A and 20B or even earlier at FIGS. 19A and 19B. As such, the gap G_{W} between opposing first semiconductor material layers 92A_{W} remains and may be greater than or substantially equal to the gap G_{N} between opposing first semiconductor material layers 92A_{N}. Formation of the second semiconductor material layers 92B will then continue through the merging of the epitaxial source/drain regions 92, and the semiconductor material layers 92B/92C will complete the growth of the epitaxial source/drain regions. By forming less of the first semiconductor material layers 92A_{W}, the second semiconductor material layer 92B_{W} has less initial surface area to grow over and will have a slower growth rate than otherwise. The growth rate of the second semiconductor material layer 92B_{W} will increase and overall be greater than the growth rate of the second semiconductor material layer 92B_{N}. In such embodiments, both of the epitaxial source/drain regions 92_{N}/92_{W} will comprise greater volumes of the second semiconductor material layers 92B as compared to those embodiments that include all stages of growth of the first semiconductor material layers 92A (e.g., as illustrated and described above with all of FIGS. 19A-21B). In either set of embodiments, contact resistance between the epitaxial source/drain regions and the subsequently formed contacts 112 will be improved.

Various advantages are achieved. Formation of some nano-FETs include selections of crystal orientation (e.g., (110) wafer orientation), widths of the fins 66, pitches of the dummy gates 76 (e.g., including replacement gate electrodes 102), and stoppage points of various stages in the formation of the epitaxial source/drain regions 92. The disclosed embodiments provide greater control over the resulting epitaxial source/drain regions 92. The various fins 66 may have a variety of widths (e.g., W_{N} and W_{W}) which could result in loading effects during formation of the epitaxial source/drain regions 92. These loading effects are circumvented by utilizing the disclosed embodiments. In particular, a narrow epitaxy 92_{N} in a narrow fin 66_{N} may be formed simultaneously with a wide epitaxy 92_{W} in a wide fin 66_{W} to achieve the desired features. For example, the disclosed embodiments ensure that the wide epitaxy 92_{W} may be formed to an adequate raised height (e.g., in relation to the raised height of the narrow epitaxy 92_{N}) in order for subsequently formed contacts 112 to have adequate contact area with the underlying epitaxial source/drain regions 92_{N}/92_{W}. As a result, the corresponding nano-FETs (and overall integrated circuit) may be fabricated at a greater yield and with improved performance and reliability.

In an embodiment, a method includes: forming a stack of semiconductor layers over a substrate; etching the stack to form a first fin and a second fin over the substrate, the first fin having a first width, the second fin having a second width, the second width being greater than the first width; etching a first recess in the first fin and a second recess in the second fin; performing a deposition process to grow a first epitaxial region in the first recess and a second epitaxial region in the second recess; wherein at a first point in the deposition process, a first raised height of the first epitaxial region is higher than a second raised height of the second epitaxial region; and wherein at a second point in the deposition process, a third raised height of the first epitaxial region is lower than a fourth raised height of the second epitaxial region, the second point being after the first point. In another embodiment, the substrate comprises a semiconductor substrate at a (110) crystal orientation. In another embodiment, the first fin is parallel to the second fin. In another embodiment, the first fin is skew perpendicular to the second fin. In another embodiment, a first growth rate of the first epitaxial region up to the first point is greater than a second growth rate of the second epitaxial region up to the first point. In another embodiment, a third growth rate of the first epitaxial region from the first point to the second point is lesser than a fourth growth rate of the second epitaxial region from the first point to the second point. In another embodiment, the method further includes, before performing the deposition process: forming a first gate structure across the first fin and a second gate structure across the second fin; removing first semiconductor layers from the stack to form voids between second semiconductor layers remaining in the stack; and forming a sacrificial material in the voids. In another embodiment, the method further includes, after performing the deposition process: replacing the first gate structure with a third gate structure; and replacing the second gate structure with a fourth gate structure.

In an embodiment, a method includes: forming a stack of alternating first semiconductor layers and second semiconductor layers over a substrate; etching the stack to form a first fin and a second fin, the first fin having a first width, the second fin having a second width, the second width being greater than the first width; forming first gates across the first fin and second gates across the second fin; etching a first recess between the first gates and a second recess between the second gates; and performing an epitaxial growth to form a first epitaxial region in the first recess and a second epitaxial region in the second recess, performing the epitaxial growth comprising: a first step comprising forming first opposing epitaxies in the first recess and second opposing epitaxies in the second recess, wherein after the first step: a first gap separates the first opposing epitaxies; and a second gap separates the second opposing epitaxies; and a second step comprising enlarging the first opposing epitaxies and the second opposing epitaxies, wherein after the second step: a third gap separates the first opposing epitaxies; and the second opposing epitaxies are merged with one another to form a second merged epitaxy. In another embodiment, performing the epitaxial growth further comprises a third step comprising enlarging the first opposing epitaxies and the second merged epitaxy, wherein after the third step the first opposing epitaxies are merged with one another to form a first merged epitaxy. In another embodiment, after the third step a first height of the first merged epitaxy is greater than a second height of the second merged epitaxy. In another embodiment, performing the epitaxial growth further comprises a fourth step comprising enlarging the first merged epitaxy and the second merged epitaxy, wherein after the fourth step a third height of the first merged epitaxy is lesser than a fourth height of the second merged epitaxy. In another embodiment, the second width is at least twice the first width. In another embodiment, a first pitch of the first gates is substantially equal to a second pitch of the second gates. In another embodiment, the substrate is part of a wafer comprising a semiconductor substrate, and wherein the semiconductor substrate has a (110) crystal orientation.

In an embodiment, a semiconductor device includes: a semiconductor substrate; a first nano-FET comprising: a first gate structure disposed across a first fin, the first fin having a first width; and a first source/drain region embedded in the first fin adjacent to the first gate structure, the first source/drain region having a first raised height from the semiconductor substrate; and a second nano-FET comprising: a second gate structure disposed across a second fin, the second fin having a second width, the second width being greater than the first width; and a second source/drain region embedded in the second fin adjacent to the second gate structure, the second source/drain region having a second raised height from the semiconductor substrate, the second raised height being greater than the first raised height. In another embodiment, the first nano-FET and the second nano-FET are disposed over the semiconductor substrate at a (110) crystal orientation. In another embodiment, the semiconductor device further includes: an interlayer dielectric disposed over the first nano-FET and the second nano-FET; a first contact plug extending through the interlayer dielectric to the first source/drain region; and a second contact plug extending through the interlayer dielectric to the second source/drain region. In another embodiment, the first contact plug has a first total contact area with the first source/drain region, wherein the second contact plug has a second total contact area with the second source/drain region, and wherein the second total contact area is greater than or equal to the first total contact area. In another embodiment, the second total contact area is substantially equal to the first total contact area.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a stack of semiconductor layers over a substrate;
etching the stack to form a first fin and a second fin over the substrate, the first fin having a first width, the second fin having a second width, the second width being greater than the first width;
etching a first recess in the first fin and a second recess in the second fin;
performing a deposition process to grow a first epitaxial region in the first recess and a second epitaxial region in the second recess;
wherein at a first point in the deposition process, a first raised height of the first epitaxial region is higher than a second raised height of the second epitaxial region; and
wherein at a second point in the deposition process, a third raised height of the first epitaxial region is lower than a fourth raised height of the second epitaxial region, the second point being after the first point.

2. The method of claim 1, wherein the substrate comprises a semiconductor substrate at a (110) crystal orientation.

3. The method of claim 2, wherein the first fin is parallel to the second fin.

4. The method of claim 2, wherein the first fin is skew perpendicular to the second fin.

5. The method of claim 1, wherein a first growth rate of the first epitaxial region up to the first point is greater than a second growth rate of the second epitaxial region up to the first point.

6. The method of claim 5, wherein a third growth rate of the first epitaxial region from the first point to the second point is lesser than a fourth growth rate of the second epitaxial region from the first point to the second point.

7. The method of claim 1, further comprising, before performing the deposition process:
forming a first gate structure across the first fin and a second gate structure across the second fin;
removing first semiconductor layers from the stack to form voids between second semiconductor layers remaining in the stack; and
forming a sacrificial material in the voids.

8. The method of claim 7, further comprising, after performing the deposition process:
replacing the first gate structure with a third gate structure; and
replacing the second gate structure with a fourth gate structure.

9. A method comprising:
forming a stack of alternating first semiconductor layers and second semiconductor layers over a substrate;
etching the stack to form a first fin and a second fin, the first fin having a first width, the second fin having a second width, the second width being greater than the first width;
forming first gates across the first fin and second gates across the second fin;
etching a first recess between the first gates and a second recess between the second gates; and
performing an epitaxial growth to form a first epitaxial region in the first recess and a second epitaxial region in the second recess, performing the epitaxial growth comprising:
a first step comprising forming first opposing epitaxies in the first recess and second opposing epitaxies in the second recess, wherein after the first step:
a first gap separates the first opposing epitaxies; and
a second gap separates the second opposing epitaxies; and
a second step comprising enlarging the first opposing epitaxies and the second opposing epitaxies, wherein after the second step:
a third gap separates the first opposing epitaxies; and
the second opposing epitaxies are merged with one another to form a second merged epitaxy.

10. The method of claim 9, wherein performing the epitaxial growth further comprises a third step comprising enlarging the first opposing epitaxies and the second merged epitaxy, wherein after the third step the first opposing epitaxies are merged with one another to form a first merged epitaxy.

11. The method of claim 10, wherein after the third step a first height of the first merged epitaxy is greater than a second height of the second merged epitaxy.

12. The method of claim 11, wherein performing the epitaxial growth further comprises a fourth step comprising enlarging the first merged epitaxy and the second merged epitaxy, wherein after the fourth step a third height of the first merged epitaxy is lesser than a fourth height of the second merged epitaxy.

13. The method of claim 9, wherein the second width is at least twice the first width.

14. The method of claim 13, wherein a first pitch of the first gates is substantially equal to a second pitch of the second gates.

15. The method of claim 9, wherein the substrate is part of a wafer comprising a semiconductor substrate, and wherein the semiconductor substrate has a (110) crystal orientation.

16. A semiconductor device comprising:
a semiconductor substrate;
a first nano-FET comprising:
a first gate structure disposed across a first fin, the first fin having a first width; and
a first source/drain region embedded in the first fin adjacent to the first gate structure, the first source/drain region having a first raised height from the semiconductor substrate; and
a second nano-FET comprising:
a second gate structure disposed across a second fin, the second fin having a second width, the second width being greater than the first width; and
a second source/drain region embedded in the second fin adjacent to the second gate structure, the second source/drain region having a second raised height from the semiconductor substrate, the second raised height being greater than the first raised height.

17. The semiconductor device of claim 16, wherein the first nano-FET and the second nano-FET are disposed over the semiconductor substrate at a (110) crystal orientation.

18. The semiconductor device of claim 16, further comprising:
an interlayer dielectric disposed over the first nano-FET and the second nano-FET;
a first contact plug extending through the interlayer dielectric to the first source/drain region; and
a second contact plug extending through the interlayer dielectric to the second source/drain region.

19. The semiconductor device of claim 18, wherein the first contact plug has a first total contact area with the first source/drain region, wherein the second contact plug has a second total contact area with the second source/drain region, and wherein the second total contact area is greater than or equal to the first total contact area.

20. The semiconductor device of claim 19, wherein the second total contact area is substantially equal to the first total contact area.
